(19) United States
(12) Patent Application Publication
(10) Pub. No.: US 2025/0240950 A1
(43) Pub. Date: Jul. 24, 2025

(54) SEMICONDUCTOR DEVICE AND METHOD OF FORMING THE SAME

(71) Applicant: SK hynix Inc., Gyeonggi-do (KR)

(72) Inventors: Hyun Woo KIM, Gyeonggi-do (KR); Su Jeong HAN, Gyeonggi-do (KR); Dong Yean OH, Gyeonggi-do (KR); Woon Ha YIM, Gyeonggi-do (KR)

(21) Appl. No.: 18/676,508

(22) Filed: May 29, 2024

(30) Foreign Application Priority Data
Jan. 23, 2024 (KR) 10-2024-0010088

(51) Int. Cl. H10B 12/00; G11C 11/408

(52) U.S. Cl. CPC H10B 12/50; G11C 11/4085

(57) ABSTRACT

A semiconductor device includes an N-well between first and second P-wells. N-type active regions including first and second N-type active regions are disposed in the N-well. A shortest distance between a boundary of the second P-well and the N-well and the second N-type active region is larger than a shortest distance between a boundary of the first P-well and the N-well and the first N-type active region. A first P-gate dielectric layer including a first modulation layer is provided on the first N-type active region. The first modulation layer includes a first intermediate modulation layer between lower and upper modulation layers. A second P-gate dielectric layer including a second modulation layer is provided on the second N-type active region. The second modulation layer includes a second intermediate modulation layer between the lower and upper modulation layers. The first intermediate modulation layer is thicker than the second intermediate modulation layer.

### CROSS-REFERENCE TO RELATED APPLICATION

The present application claims priority under 35 U.S.C. § 119 (a) to Korean Patent Application No. 10-2024-0010088 filed on Jan. 23, 2024, which is incorporated herein by reference in its entirety.

### BACKGROUND

### 1. Technical Field

Various embodiments of the present disclosure generally relate to a semiconductor device including a sub word line driver and a method of forming the same.

### 2. Related Art

A semiconductor device includes transistors which configure a memory cell array and a peripheral circuit. According to high integration of the semiconductor device, the size and gap of the transistors are gradually shrinking. Reducing the size and gap of the transistors causes various problems such as a well proximity effect (WPE) in a manufacturing process. Thus, dispersion of the electrical characteristics of the transistors may increase.

### SUMMARY

Various embodiments of the present disclosure are directed to providing a semiconductor device which reduces dispersion of electrical characteristics and is advantageous for high integration, and a method of forming the same.

In some embodiments of the present disclosure, a semiconductor device may include a first P-well, a second P-well and an N-well between the first P-well and the second P-well in a substrate. A plurality of N-type active regions which are delimited within the N-well may be disposed. The plurality of N-type active regions may include a first N-type active region adjacent to the first P-well and a second N-type active region adjacent to the second P-well. A shortest distance between a boundary of the second P-well and the N-well and the second N-type active region may be larger than a shortest distance between a boundary of the first P-well and the N-well and the first N-type active region. A first P-gate dielectric layer which is disposed on the first N-type active region and includes a first modulation layer may be provided. The first modulation layer may include a first intermediate modulation layer between a lower modulation layer and an upper modulation layer. A second P-gate dielectric layer which is disposed on the second N-type active region and includes a second modulation layer may be provided. The second modulation layer may include a second intermediate modulation layer between the lower modulation layer and the upper modulation layer. The first intermediate modulation layer may be thicker than the second intermediate modulation layer. A first P-gate electrode may be disposed on the first P-gate dielectric layer. A second P-gate electrode may be disposed on the second P-gate dielectric layer.

In some embodiments of the present disclosure, a semiconductor device may include a first P-well, a second P-well and an N-well including a first N-well and a second N-well between the first P-well and the second P-well in a substrate. The first N-well may be adjacent to the first P-well, and the second N-well may be adjacent to the second P-well. A plurality of N-type active regions which are delimited within the first N-well may be disposed. The plurality of N-type active regions may include a first N-type active region adjacent to the first P-well and a second N-type active region adjacent to the second N-well. A shortest distance between a boundary of the first P-well and the first N-well and the first N-type active region may be substantially the same as a shortest distance between a boundary of the first N-well and the second N-well and the second N-type active region. A first P-gate dielectric layer which is disposed on the first N-type active region and includes a first modulation layer may be provided. A second P-gate dielectric layer which is disposed on the second N-type active region and includes a second modulation layer may be provided. The first modulation layer may be thicker than the second modulation layer. A first P-gate electrode which includes a first P-work function metal layer on the first P-gate dielectric layer may be provided. A second P-gate electrode which includes a second P-work function metal layer on the second P-gate dielectric layer may be provided. The first P-work function metal layer may be thicker than the second P-work function metal layer.

In some embodiments of the present disclosure, a semiconductor device may include a first P-well, a second P-well and an N-well between the first P-well and the second P-well in a substrate. A plurality of N-type active regions which are delimited within the N-well may be disposed. The plurality of N-type active regions may include a first N-type active region adjacent to the first P-well and a second N-type active region adjacent to the second P-well. A shortest distance between a boundary of the second P-well and the N-well and the second N-type active region may be larger than a shortest distance between a boundary of the first P-well and the N-well and the first N-type active region. A first P-gate electrode which includes a first P-work function metal layer on the first N-type active region may be provided. A second P-gate electrode which includes a second P-work function metal layer on the second N-type active region may be provided. The first P-work function metal layer may be thicker than the second P-work function metal layer. P-gate dielectric layers may be disposed between the first N-type active region and the first P-gate electrode and between the second N-type active region and the second P-gate electrode.

In some embodiments of the present disclosure, a semiconductor device may include a first P-well, a second P-well and an N-well including a first N-well and a second N-well between the first P-well and the second P-well in a substrate. The first N-well may be adjacent to the first P-well, and the second N-well may be adjacent to the second P-well. A plurality of N-type active regions which are delimited within the first N-well may be disposed. The plurality of N-type active regions may include a first N-type active region adjacent to the first P-well and a second N-type active region adjacent to the second N-well. A shortest distance between a boundary of the first P-well and the first N-well and the first N-type active region may be substantially the same as a shortest distance between a boundary of the first N-well and the second N-well and the second N-type active region. P-gate dielectric layers may be disposed on the first N-type active region and the second N-type active region. P-gate electrodes may be disposed on the P-gate dielectric layers.

In some embodiments of the present disclosure, a semiconductor device may include a first P-well, a second P-well and an N-well including a first N-well and a second N-well between the first P-well and the second P-well in a substrate. The first N-well may be adjacent to the first P-well, and the second N-well may be adjacent to the second P-well. A plurality of N-type active regions which are delimited within the N-well may be disposed. The plurality of N-type active regions may include a first N-type active region which is adjacent to the first P-well and is delimited within the first N-well and a second N-type active region which is adjacent to the second P-well and is delimited within the second N-well. A shortest distance between a boundary of the second P-well and the second N-well and the second N-type active region may be larger than a shortest distance between a boundary of the first P-well and the first N-well and the first N-type active region. P-gate dielectric layers may be disposed on the first N-type active region and the second N-type active region. P-gate electrodes may be disposed on the P-gate dielectric layers.

In some embodiments of the present disclosure, a semiconductor device may include a first P-well, a second P-well and an N-well including a first N-well and a second N-well between the first P-well and the second P-well in a substrate. The first N-well may be adjacent to the first P-well, and the second N-well may be adjacent to the second P-well. A plurality of N-type active regions which are delimited within the N-well may be disposed. The plurality of N-type active regions may include a first N-type active region which is adjacent to the first P-well and is delimited within the first N-well and a second N-type active region which is adjacent to the second P-well and is delimited within the second N-well. A shortest distance between a boundary of the second P-well and the second N-well and the second N-type active region may be larger than a shortest distance between a boundary of the first P-well and the first N-well and the first N-type active region. A first P-gate dielectric layer which is disposed on the first N-type active region and includes a first modulation layer may be provided. A second P-gate dielectric layer which is disposed on the second N-type active region and includes a second modulation layer may be provided. The first modulation layer may be thicker than the second modulation layer. A first P-gate electrode which includes a first P-work function metal layer on the first P-gate dielectric layer may be disposed. A second P-gate electrode which includes a second P-work function metal layer on the second P-gate dielectric layer may be disposed. The first P-work function metal layer may be thicker than the second P-work function metal layer.

According to the embodiments of the present disclosure, it is possible to implement a semiconductor device which reduces dispersion of the electrical characteristics of transistors and is advantageous for high integration.

### BRIEF DESCRIPTION OF THE DRAWINGS

FIG. 1 is a cross-sectional view for describing a semiconductor device based some embodiments of the present disclosure.

FIG. 2 is a layout diagram for describing the semiconductor device based on some embodiments of the present disclosure.

FIGS. 3 to 17 are cross-sectional views for describing semiconductor devices based on embodiments of the present disclosure.

FIGS. 18 and 19 are flowcharts for describing a method of forming a semiconductor device based some embodiments of the present disclosure.

FIGS. 20 to 30 are cross-sectional views for describing the method of forming a semiconductor device based on some embodiments of the present disclosure.

### DETAILED DESCRIPTION

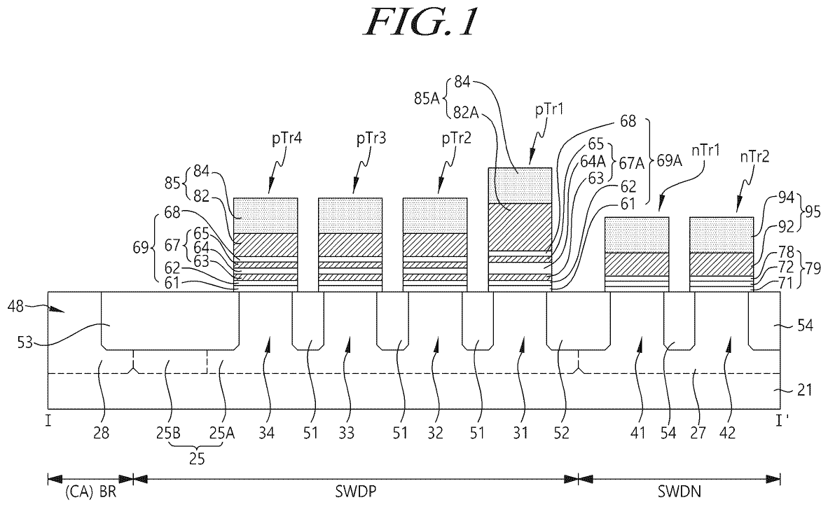

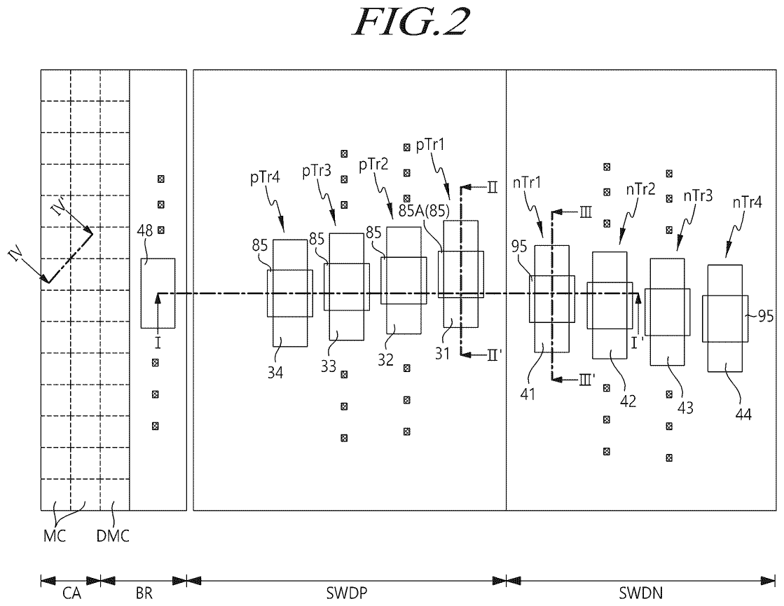

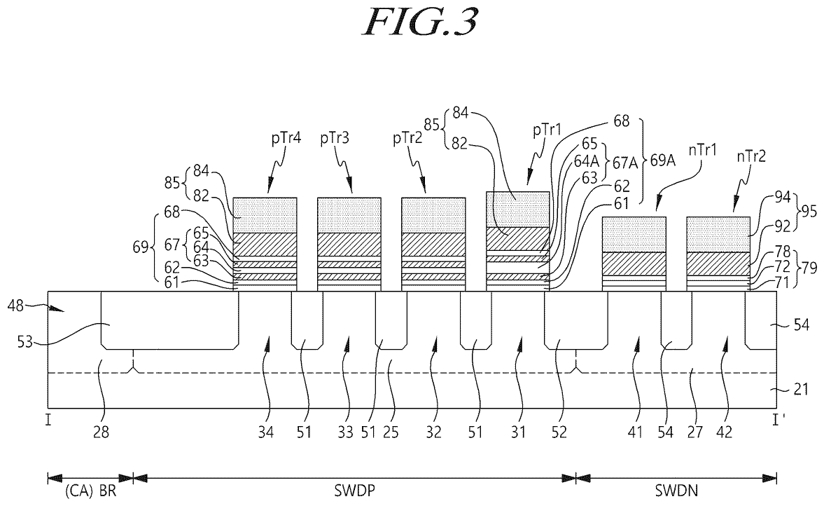

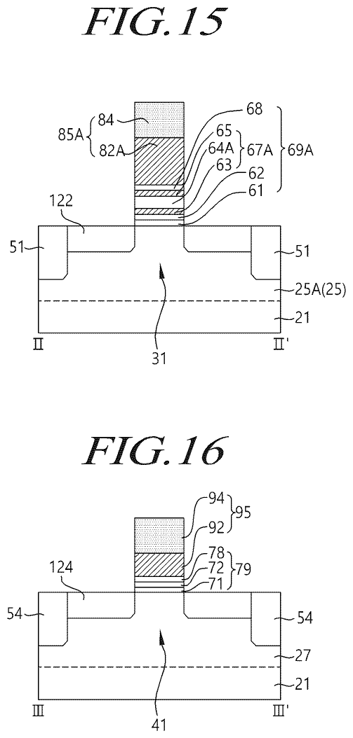

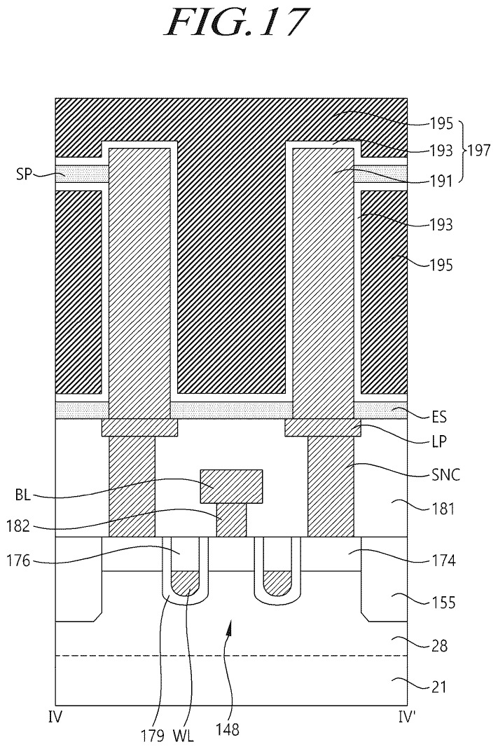

FIG. 1 is a cross-sectional view for describing a semiconductor device and FIG. 2 is a layout diagram based on some embodiments of the present disclosure. FIGS. 3 to 17 are cross-sectional views for describing semiconductor devices based on embodiments of the present disclosure. FIGS. 1 and 3 to 14 are cross-sectional views taken along the line I-I′ of FIG. 2, FIG. 15 is a cross-sectional view taken along the line II-II′ of FIG. 2, FIG. 16 is a cross-sectional view taken along the line III-III′ of FIG. 2, and FIG. 17 is a cross-sectional view taken along the line IV-IV′ of FIG. 2.

Referring to FIG. 1, the semiconductor device based on some embodiments of the present disclosure may include a substrate 21, an N-well 25, a first P-well 27, a second P-well 28, active regions 31, 32, 33, 34, 41, 42 and 48, isolation patterns 51, 52, 53 and 54, gate dielectric layers 69, 69A and 79, and gate electrodes 85, 85A and 95. The substrate 21 may include a cell region CA (see FIG. 2), a boundary region BR, a P-type sub word line driver region SWDP, and an N-type sub word line driver region SWDN. The N-well 25 may include a first N-well 25A and a second N-well 25B.

The active regions 31, 32, 33, 34, 41, 42 and 48 may include N-type active regions 31, 32, 33 and 34, P-type active regions 41 and 42, and a dummy active region 48. The N-type active regions 31, 32, 33 and 34 include a first N-type active region 31, a second N-type active region 32, a third N-type active region 33, and a fourth N-type active region 34. The P-type active regions 41 and 42 may include a first P-type active region 41 and a second P-type active region 42. The first to the fourth N-type active regions 31 to 34 are assigned sequential numbers in that sequence for the sake of convenience in description, and may be assigned different sequential numbers in some embodiments. For example, in some embodiments, the fourth N-type active region 34 may be referred to as a second N-type active region, the second N-type active region 32 may be referred to as a third N-type active region, and the third N-type active region 33 may be referred to as a fourth N-type active region.

The N-type active regions 31, 32, 33 and 34 may be disposed in the P-type sub word line driver region SWDP, the P-type active regions 41 and 42 may be disposed in the N-type sub word line driver region SWDN, and the dummy active region 48 may be disposed in the boundary region BR. The isolation patterns 51, 52, 53 and 54 may include first isolation patterns 51, a second isolation pattern 52, a third isolation pattern 53, and fourth isolation patterns 54.

The gate dielectric layers 69, 69A and 79 may include a first P-gate dielectric layer 69A, a second P-gate dielectric layer 69 and an N-gate dielectric layer 79. The first P-gate dielectric layer 69A may include a P-interface layer 61, a P-dielectric layer 62, a first modulation layer 67A and a P-capping layer 68 which are sequentially stacked. The first modulation layer 67A may include a lower modulation layer 63, a first intermediate modulation layer 64A and an upper modulation layer 65 which are sequentially stacked. The second P-gate dielectric layer 69 may include the P-interface layer 61, the P-dielectric layer 62, a second modulation layer 67 and the P-capping layer 68 which are sequentially stacked. The second modulation layer 67 may include the lower modulation layer 63, a second intermediate modulation layer 64 and the upper modulation layer 65 which are sequentially stacked. The N-gate dielectric layer 79 may include an N-interface layer 71, an N-dielectric layer 72 and an N-capping layer 78 which are sequentially stacked.

In the embodiment of FIG. 1, the gate electrodes 85, 85A and 95 may include a first P-gate electrode 85A, a second P-gate electrode 85 and an N-gate electrode 95. The first P-gate electrode 85A may include a first P-work function metal layer 82A and a P-gate conductive layer 84 which are sequentially stacked. The second P-gate electrode 85 may include a second P-work function metal layer 82 and the P-gate conductive layer 84 which are sequentially stacked. The N-gate electrode 95 may include an N-work function metal layer 92 and an N-gate conductive layer 94 which are sequentially stacked over the N-gate dielectric layer 79. The N-work function metal layer 92 may be positioned on the n-capping layer 78 of the N-gate dielectric layer 79.

In some embodiments, the P-interface layer 61 and the N-interface layer 71 may include an insulating material such as silicon oxide, silicon oxynitride or a combination thereof. The P-dielectric layer 62 and the N-dielectric layer 72 may include HfSiON, HfO2, HfON, SION, ZrSiO4, Y2O3, Ta2O5, BaO, HfSiO, MgO, Al2O3, Si3N4, CaO, LaLuO2 or a combination thereof. The lower modulation layer 63 may include TiN, TiCN, TaN, WN, TiAl, MoN or a combination thereof. The first intermediate modulation layer 64A and the second intermediate modulation layer 64 may include Al2O3, HfO2 or a combination thereof. The upper modulation layer 65 may include TiN, TiCN, TaN, WN, TiAl, MoN or a combination thereof. The P-capping layer 68 and the N-capping layer 78 may include LaO, La2O3, Y2O3, ScO2 or a combination thereof. The first P-work function metal layer 82A, the second P-work function metal layer 82 and the N-work function metal layer 92 may include TiN, TiCN, TaN, WN, TiAl, MoN or a combination thereof. The P-gate conductive layer 84 and the N-gate conductive layer 94 may include doped polysilicon, SiGe, SiC, Si or a combination thereof.

Referring to FIG. 2, the semiconductor device based on some embodiments of the present disclosure may include the cell region CA, the boundary region BR and the sub word line driver regions SWDP and SWDN. The boundary region BR may be continuous to one side of the cell region CA. The boundary region BR may be disposed between the cell region CA and the sub word line driver regions SWDP and SWDN. The sub word line driver regions SWDP and SWDN may include the P-type sub word line driver region SWDP and the N-type sub word line driver region SWDN. The P-type sub word line driver region SWDP may be disposed between the boundary region BR and the N-type sub word line driver region SWDN.

Memory cells MC may be disposed in the cell region CA. Dummy memory cells DMC and dummy active regions 48 may be disposed in the boundary region BR. P-type transistors pTr1, pTr2, pTr3 and pTr4 may be disposed in the P-type sub word line driver region SWDP, and N-type transistors nTr1, nTr2, nTr3 and nTr4 may be disposed in the N-type sub word line driver region SWDN.

The P-type transistors pTr1, pTr2, pTr3 and pTr4 may include a first P-type transistor pTr1, a second P-type transistor pTr2, a third P-type transistor pTr3 and a fourth P-type transistor pTr4. The first P-type transistor pTr1 may be disposed adjacent to the boundary between the P-type sub word line driver region SWDP and the N-type sub word line driver region SWDN. The fourth P-type transistor pTr4 may be disposed relatively far away from the boundary between the P-type sub word line driver region SWDP and the N-type sub word line driver region SWDN. The fourth P-type transistor pTr4 may be disposed relatively close to the boundary between the P-type sub word line driver region SWDP and the boundary region BR. The second P-type transistor pTr2 may be disposed between the first P-type transistor pTr1 and the fourth P-type transistor pTr4. The third P-type transistor pTr3 may be disposed between the second P-type transistor pTr2 and the fourth P-type transistor pTr4. The gaps between the P-type transistors pTr1, pTr2, pTr3 and pTr4 may be substantially the same.

The first P-type transistors pTr1 to the fourth P-type transistors pTr4 are assigned sequential numbers in that sequence for the sake of convenience in description, and may be assigned different sequential numbers in some embodiments. In some embodiments, the fourth P-type transistor pTr4 may be referred to as a second P-type transistor, the second P-type transistor pTr2 may be referred to as a third P-type transistor, and the third P-type transistor pTr3 may be referred to as a fourth P-type transistor.

The N-type transistors nTr1, nTr2, nTr3 and nTr4 may include a first N-type transistor nTr1, a second N-type transistor nTr2, a third N-type transistor nTr3 and a fourth N-type transistor nTr4. The first N-type transistor nTr1 may be disposed adjacent to the boundary between the P-type sub word line driver region SWDP and the N-type sub word line driver region SWDN. The fourth N-type transistor nTr4 may be disposed relatively far away from the boundary between the P-type sub word line driver region SWDP and the N-type sub word line driver region SWDN. The second N-type transistor nTr2 may be disposed between the first N-type transistor nTr1 and the fourth N-type transistor nTr4. The third N-type transistor nTr3 may be disposed between the second N-type transistor nTr2 and the fourth N-type transistor nTr4. The gaps between the N-type transistors nTr1, nTr2, nTr3 and nTr4 may be substantially the same.

The P-type transistors pTr1, pTr2, pTr3 and pTr4 may include respective N-type active regions 31, 32, 33 and 34 and the P-gate electrodes 85 and 85A. The N-type transistors nTr1, nTr2, nTr3 and nTr4 may include respective P-type active regions 41, 42, 43 and 44 and the N-gate electrodes 95. The P-type active regions 41, 42, 43 and 44 may include the first P-type active region 41, the second P-type active region 42, a third P-type active region 43 and a fourth P-type active region 44.

The memory cells MC may include volatile memories, nonvolatile memories or combinations thereof. The memory cells MC may include dynamic random access memories (DRAMs), static random access memories (SRAMs), flash memories, magnetoresistive random access memories (MRAMs), phase change random access memories (PRAMs), ferroelectric random access memories (FRAMs). resistive random access memories (RRAMs) or combinations thereof.

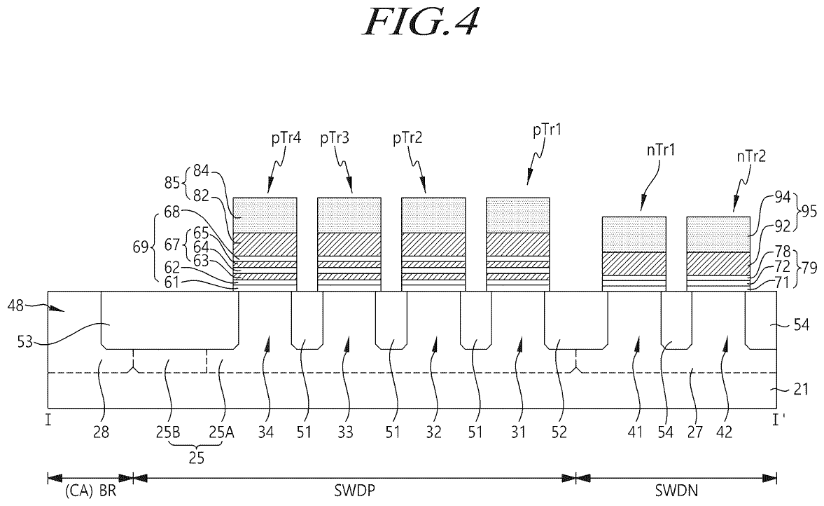

Referring to FIGS. 1 and 2, in the substrate 21, the N-well 25 may be disposed in the P-type sub word line driver region SWDP, and the first P-well 27 may be disposed in the N-type sub word line driver region SWDN, and the second P-well 28 may be disposed in the cell region CA and the boundary region BR. The N-type active regions 31, 32, 33 and 34 may be disposed in the first N-well 25A, the P-type active regions 41, 42, 43 and 44 may be disposed in the first P-well 27, and the dummy active region 48 may be disposed in the second P-well 28. Regarding the configurations of the first and second N-wells 25A and 25B, description will be made later with reference to FIG. 4.

The first N-type active region 31 may be disposed adjacent to the boundary between the P-type sub word line driver region SWDP and the N-type sub word line driver region SWDN. The first N-type active region 31 may be disposed adjacent to the boundary between the first N-well 25A and the first P-well 27. The fourth N-type active region 34 may be disposed relatively far away from the boundary between the P-type sub word line driver region SWDP and the N-type sub word line driver region SWDN. The fourth N-type active region 34 may be disposed relatively close to the boundary between the P-type sub word line driver region SWDP and the boundary region BR. The fourth N-type active region 34 may be disposed adjacent to the boundary between the first and second N-wells 25A and 25B. The shortest distance between the fourth N-type active region 34 and the boundary of the first and second N-wells 25A and 25B may be substantially the same as the shortest distance between the first N-type active region 31 and the boundary of the first N-well 25A and the first P-well 27. The second N-type active region 32 may be disposed between the first N-type active region 31 and the fourth N-type active region 34. The third N-type active region 33 may be disposed between the second N-type active region 32 and the fourth N-type active region 34.

The first P-type active region 41 may be disposed adjacent to the boundary between the P-type sub word line driver region SWDP and the N-type sub word line driver region SWDN. The first P-type active region 41 may be disposed adjacent to the boundary between the first N-well 25A and the first P-well 27. The fourth P-type active region 44 may be disposed relatively far away from the boundary between the P-type sub word line driver region SWDP and the N-type sub word line driver region SWDN. The second P-type active region 42 may be disposed between the first P-type active region 41 and the fourth P-type active region 44. The third P-type active region 43 may be disposed between the second P-type active region 42 and the fourth P-type active region 44. The first P-type active region 41 may be disposed between the second P-type active region 42 and the first N-type active region 31.

The first isolation patterns 51 may be disposed in the P-type sub word line driver region SWDP. The first isolation patterns 51 may be disposed between the N-type active regions 31, 32, 33 and 34. The N-type active regions 31, 32, 33 and 34 may have similar sizes and shapes. The horizontal widths of the respective N-type active regions 31, 32, 33 and 34 may be substantially the same. The gaps between the N-type active regions 31, 32, 33 and 34 may be substantially the same. The respective first isolation patterns 51 may have substantially the same horizontal width.

The second isolation pattern 52 may be disposed adjacent to the boundary between the P-type sub word line driver region SWDP and the N-type sub word line driver region SWDN. The second isolation pattern 52 may be disposed between the first N-type active region 31 and the first P-type active region 41. The boundary between the first N-well 25A and the first P-well 27 may be aligned or located under the second isolation pattern 52. The gap between the first N-type active region 31 and the first P-type active region 41 may be larger than the gap between the first N-type active region 31 and the second N-type active region 32. The horizontal width of the second isolation pattern 52 may be larger than the horizontal width of each of the first isolation patterns 51.

The third isolation pattern 53 may be disposed adjacent to the boundary between the P-type sub word line driver region SWDP and the boundary region BR. The third isolation pattern 53 may be disposed between the fourth N-type active region 34 and the dummy active region 48. The second N-well 25B may be delimited under the third isolation pattern 53. The boundary between the second N-well 25B and the second P-well 28 may be aligned or located under the third isolation pattern 53. The gap between the fourth N-type active region 34 and the dummy active region 48 may be larger than the gap between the first N-type active region 31 and the first P-type active region 41. The horizontal width of the third isolation pattern 53 may be larger than the horizontal width of the second isolation pattern 52.

The fourth isolation patterns 54 may be formed in the N-type sub word line driver region SWDN. The P-type active regions 41, 42, 43 and 44 may have similar sizes and shapes. The horizontal widths of the respective P-type active regions 41, 42, 43 and 44 may be substantially the same. The gaps between the P-type active regions 41, 42, 43 and 44 may be substantially the same. The fourth isolation patterns 54 may be formed between the P-type active regions 41, 42, 43 and 44 (only 41 and 42 are illustrated for avoiding overcrowding the drawing). The gaps between the P-type active regions 41, 42, 43 and 44 may be smaller than the gap between the first N-type active region 31 and the first P-type active region 41. The horizontal width of each of the fourth isolation patterns 54 may be smaller than the horizontal width of the second isolation pattern 52.

The first P-gate dielectric layer 69A and the first P-gate electrode 85A may be sequentially stacked over or, as illustrated, on the first N-type active region 31. The second P-gate dielectric layer 69 and the second P-gate electrode 85 may be sequentially stacked over or, as illustrated, on each of the second to fourth N-type active regions 32, 33 and 34. The N-gate dielectric layer 79 and the N-gate electrode 95 may be sequentially stacked over or, as illustrated, on each of the P-type active regions 41, 42, 43 and 44 (only 41 and 42 are illustrated for avoiding overcrowding the drawing).

The first intermediate modulation layer 64A in the first P-gate dielectric layer 69A may be thicker than the second intermediate modulation layer 64 in the second P-gate dielectric layer 69. Regarding the configurations of the first intermediate modulation layer 64A and the second intermediate modulation layer 64, further description will be made below with reference to FIG. 3. As shown in the embodiment of FIG. 1, the first P-work function metal layer 82A in the first P-gate electrode 85A may be thicker than the second P-work function metal layer 82 in the second P-gate electrode 85. Regarding the configurations of the first P-work function metal layer 82A and the second P-work function metal layer 82, further description is made later with reference to FIG. 8.

Referring to FIG. 3, the boundary between the N-well 25 and the first P-well 27 may be aligned or located under the second isolation pattern 52. The boundary between the N-well 25 and the second P-well 28 may be aligned or located under the third isolation pattern 53. The shortest distance between the boundary of the N-well 25 and the first P-well 27 and the first N-type active region 31 may be smaller than the shortest distance between the boundary of the N-well 25 and the second P-well 28 and the fourth N-type active region 34.

The first P-gate dielectric layer 69A and the second P-gate electrode 85 may be sequentially stacked over or, as illustrated, on the first N-type active region 31. The second P-gate dielectric layer 69 and the second P-gate electrode 85 may be sequentially stacked over or, as illustrated, on each of the second to fourth N-type active regions 32, 33 and 34. The N-gate dielectric layer 79 and the N-gate electrode 95 may be sequentially stacked over or, as illustrated, on each of the P-type active regions, e.g., 41, 42, 43 and 44. It is noted that in FIG. 3 only two of the P-type active regions are shown, however all four P-type active regions can be shown in FIG. 2.

The first P-gate dielectric layer 69A may include the P-interface layer 61, the P-dielectric layer 62, the first modulation layer 67A and the P-capping layer 68 which are sequentially stacked. The first modulation layer 67A may include the lower modulation layer 63, the first intermediate modulation layer 64A and the upper modulation layer 65 which are sequentially stacked. The second P-gate dielectric layer 69 may include the P-interface layer 61, the P-dielectric layer 62, the second modulation layer 67 and the P-capping layer 68 which are sequentially stacked. The second modulation layer 67 may include the lower modulation layer 63, the second intermediate modulation layer 64 and the upper modulation layer 65 which are sequentially stacked. The N-gate dielectric layer 79 may include the N-interface layer 71, the N-dielectric layer 72 and the N-capping layer 78 which are sequentially stacked.

In an embodiment, the first modulation layer 67A and the second modulation layer 67 may include a dipole structure. The first intermediate modulation layer 64A and the second intermediate modulation layer 64 may include Al2O3. The lower modulation layer 63 and the upper modulation layer 65 may include TiN. The first intermediate modulation layer 64A may be thicker than the second intermediate modulation layer 64. The first modulation layer 67A may be thicker than the second modulation layer 67. The first P-gate dielectric layer 69A may be thicker than the second P-gate dielectric layer 69.

Due to the well proximity effect (WPE), the N-type impurity concentration of the first N-type active region 31 may be higher than the N-type impurity concentrations of the second to fourth N-type active regions 32, 33 and 34. By modulating the thickness of the first intermediate modulation layer 64A, the threshold voltage of the first P-type transistor pTr1 may be controlled. By modulating the thickness of the first intermediate modulation layer 64A, the threshold voltage of the first P-type transistor pTr1 may be controlled to be similar to those of the second to fourth P-type transistors pTr2, pTr3 and pTr4. By modulating the thickness of the first intermediate modulation layer 64A, dispersion of the electrical characteristics of the P-type transistors pTr1, pTr2, pTr3 and pTr4 may be reduced.

The second P-gate electrode 85 may include the second P-work function metal layer 82 and the P-gate conductive layer 84 which are sequentially stacked. The N-gate electrode 95 may include the N-work function metal layer 92 and the N-gate conductive layer 94. Referring to FIG. 4, the N-well 25 may include the first and second N-wells 25A and 25B. The first and second N-wells 25A and 25B may be formed using different ion implantation masks and/or the first and second N-wells 25A and 25B may be formed using different ion implantation processes. The boundary between the first and second N-wells 25A and 25B may be aligned or located under the third isolation pattern 53. The second N-well 25B may be delimited under the third isolation pattern 53. The second N-well 25B may be positioned in its entirety under the third isolation pattern 53.

The second P-gate dielectric layer 69 and the second P-gate electrode 85 may be sequentially stacked over or, as illustrated, on each of the N-type active regions 31, 32, 33 and 34. The N-gate dielectric layer 79 and the N-gate electrode 95 may be sequentially stacked over or, as illustrated, on each of the P-type active regions 41, 42, 43 and 44. In FIG. 4 only two of the four P-type active regions are illustrated.

The shortest distance between the boundary of the first and second N-wells 25A and 25B and the fourth N-type active region 34 may be substantially the same as the shortest distance between the boundary of the first N-well 25A and the first P-well 27 and the first N-type active region 31. Due to a reduction in the well proximity effect (WPE), the N-type impurity concentrations of the N-type active regions 31, 32, 33 and 34 may be similarly controlled. It is, thus, possible to reduce the dispersion of the electrical characteristics of the P-type transistors pTr1, pTr2, pTr3 and pTr4.

Referring to FIG. 5, the N-well 25 may include a third N-well 25C and a fourth N-well 25D. The third and fourth N-wells 25C and 25D may be formed using different ion implantation masks. The third and the fourth N-wells 25C and 25D may be formed using different ion implantation processes. The first N-type active region 31 may be delimited within the third N-well 25C, and the second to fourth N-type active regions 32, 33 and 34 may be delimited within the fourth N-well 25D. The boundary between the third and fourth N-wells 25C and 25D may be aligned between the first N-type active region 31 and the second N-type active region 32. The boundary between the third N-well 25C and the first P-well 27 may be aligned or located under the second isolation pattern 52. The boundary between the fourth N-well 25D and the second P-well 28 may be aligned or located under the third isolation pattern 53.

By using the different ion implantation masks and different ion implantation processes, dispersion of the N-type impurity concentrations (i.e., non-uniformity of the N-type impurity concentrations) of the N-type active regions 31, 32, 33 and 34 may be reduced. According to this configuration, it is possible to reduce dispersion of the electrical characteristics of the P-type transistors pTr1, pTr2, pTr3 and pTr4.

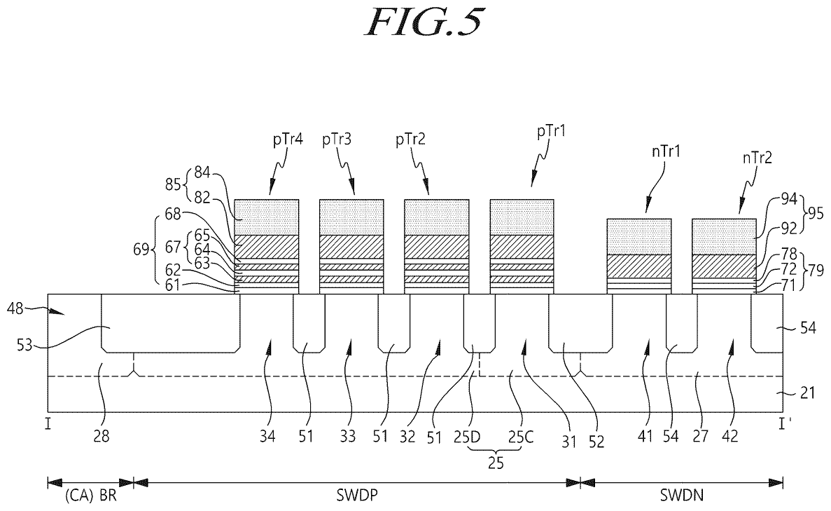

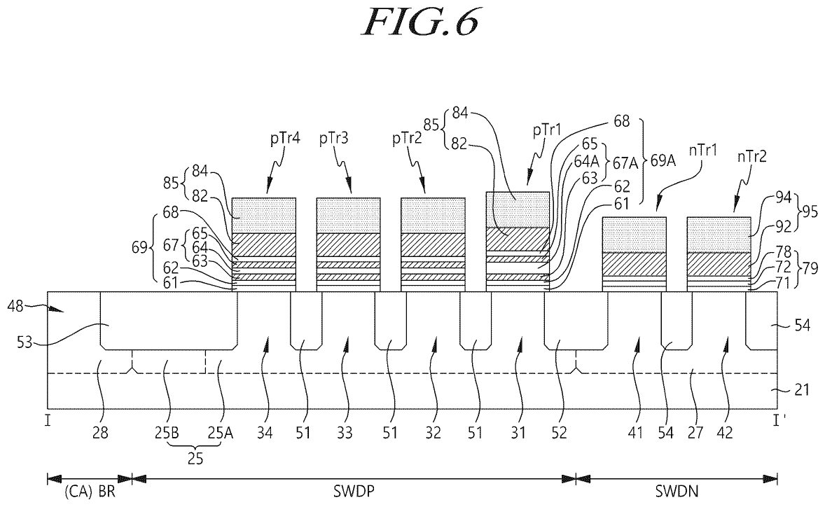

Referring to FIG. 6, the N-well 25 may include the first and the second N-wells 25A and 25B. Dispersion of the N-type impurity concentrations (i.e., non-uniformity of the N-type impurity concentrations) of the N-type active regions 31, 32, 33 and 34 may be reduced. The first P-gate dielectric layer 69A and the second P-gate electrode 85 may be sequentially stacked over or, as illustrated, on the first N-type active region 31. The second P-gate dielectric layer 69 and the second P-gate electrode 85 may be sequentially stacked over or, as illustrated, on each of the second to fourth N-type active regions 32, 33 and 34. The first intermediate modulation layer 64A in the first P-gate dielectric layer 69A may be thicker than the second intermediate modulation layer 64 in the second P-gate dielectric layer 69. The threshold voltage of the first P-type transistor pTr1 may be controlled to be similar to those of the second to fourth P-type transistors pTr2, pTr3 and pTr4. According to this configuration, it is possible to reduce dispersion of the electrical characteristics of the P-type transistors pTr1, pTr2, pTr3 and pTr4.

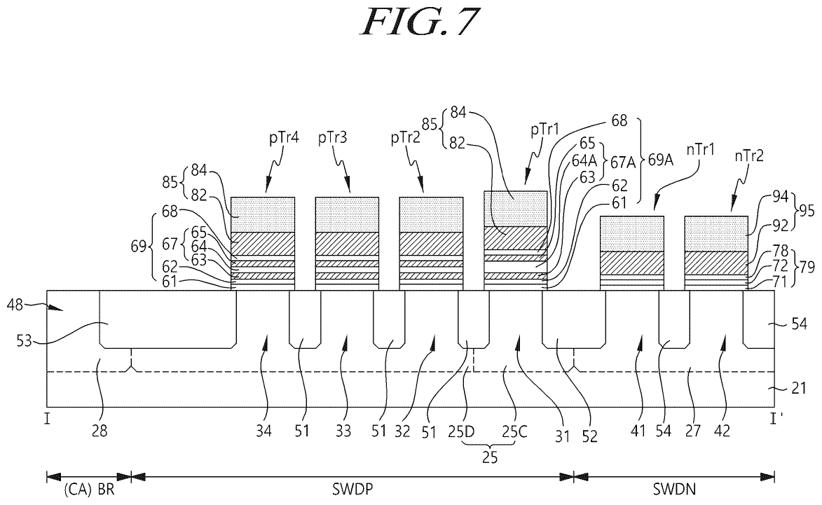

Referring to FIG. 7, the N-well 25 may include the third and fourth N-wells 25C and 25D. Dispersion of the N-type impurity concentrations (i.e., non-uniformity of the N-type impurity concentrations) of the N-type active regions 31, 32, 33 and 34 may be reduced. The first P-gate dielectric layer 69A and the second P-gate electrode 85 may be sequentially stacked over or, as illustrated, on the first N-type active region 31. The second P-gate dielectric layer 69 and the second P-gate electrode 85 may be sequentially stacked over or, as illustrated, on each of the second to fourth N-type active regions 32, 33 and 34. The threshold voltage of the first P-type transistor pTr1 may be controlled to be similar to those of the second to fourth P-type transistors pTr2, pTr3 and pTr4. According to this configuration, it is possible to reduce dispersion of the electrical characteristics of the P-type transistors pTr1, pTr2, pTr3 and pTr4.

Referring to FIG. 8, the second P-gate dielectric layer 69 and the first P-gate electrode 85A may be sequentially stacked over or, as illustrated, on the first N-type active region 31. The second P-gate dielectric layer 69 and the second P-gate electrode 85 may be sequentially stacked over or, as illustrated, on each of the second to fourth N-type active regions 32, 33 and 34. The N-gate dielectric layer 79 and the N-gate electrode 95 may be sequentially stacked over or, as illustrated, on each of the P-type active regions 41, 42, 43 and 44 (only 41 and 42 are illustrated for avoiding overcrowding the drawing).

The second P-gate dielectric layer 69 may include the P-interface layer 61 and the P-dielectric layer 62 which are sequentially stacked. The N-gate dielectric layer 79 may include the N-interface layer 71, the N-dielectric layer 72 and the N-capping layer 78 which are sequentially stacked over or, as illustrated, on each of the P-type active regions 41, 42, 43, and 44.

The first P-gate electrode 85A may include the first P-work function metal layer 82A and the P-gate conductive layer 84. The second P-gate electrode 85 may include the second P-work function metal layer 82 and the P-gate conductive layer 84. The N-gate electrode 95 may include the N-work function metal layer 92 and the N-gate conductive layer 94.

In some embodiments, the first P-work function metal layer 82A, the second P-work function metal layer 82 and the N-work function metal layer 92 may include TiN. The first P-work function metal layer 82A may be thicker than the second P-work function metal layer 82.

The N-type impurity concentration of the first N-type active region 31 may be higher than the N-type impurity concentrations of the second to fourth N-type active regions 32, 33 and 34. By modulating the thickness of the first P-work function metal layer 82A, the threshold voltage of the first P-type transistor pTr1 may be controlled. By modulating the thickness of the first P-work function metal layer 82A, the threshold voltage of the first P-type transistor pTr1 may be controlled to be similar to those of the second to fourth P-type transistors pTr2, pTr3 and pTr4. By modulating the thickness of the first P-work function metal layer 82A, dispersion of the electrical characteristics of the P-type transistors pTr1, pTr2, pTr3 and pTr4 may be reduced.

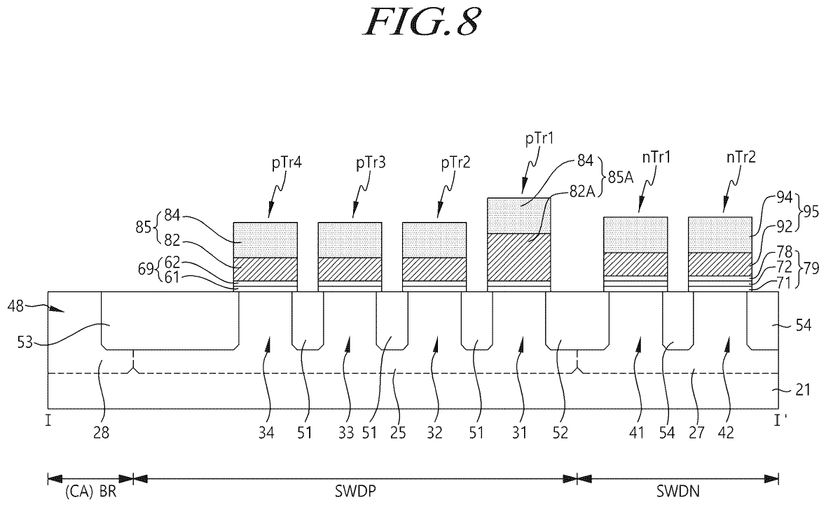

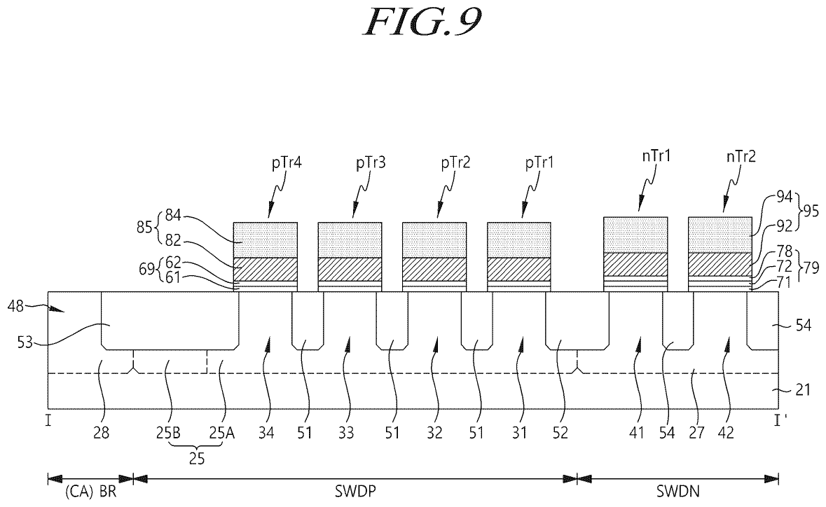

Referring to FIG. 9, the N-well 25 may include the first and second N-wells 25A and 25B. Dispersion of the N-type impurity concentrations (i.e., non-uniformity of the N-type impurity concentrations) of the N-type active regions 31, 32, 33 and 34 may be reduced. The second P-gate dielectric layer 69 and the second P-gate electrode 85 may be sequentially stacked over or, as illustrated, on each of the N-type active regions 31, 32, 33 and 34. The N-gate dielectric layer 79 and the N-gate electrode 95 may be sequentially stacked over or, as illustrated, on each of the P-type active regions 41, 42, 43 and 44 (only 41 and 42 are illustrated for avoiding overcrowding the drawing). According to this configuration, it is possible to reduce dispersion of the electrical characteristics of the P-type transistors pTr1, pTr2, pTr3 and pTr4.

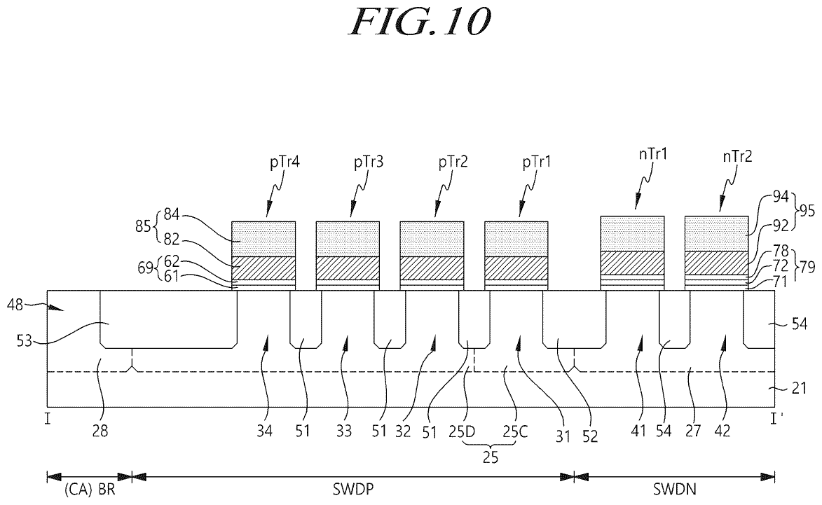

Referring to FIG. 10, the N-well 25 may include the third and fourth N-wells 25C and 25D. Dispersion of the N-type impurity concentrations (i.e., non-uniformity of the N-type impurity concentrations) of the N-type active regions 31, 32, 33 and 34 may be reduced. The second P-gate dielectric layer 69 and the second P-gate electrode 85 may be sequentially stacked over or, as illustrated, on each of the N-type active regions 31, 32, 33 and 34. The N-gate dielectric layer 79 and the N-gate electrode 95 may be sequentially stacked over or, as illustrated, on each of the P-type active regions 41, 42, 43 and 44 (only 41 and 42 are illustrated for avoiding overcrowding the drawing). According to this configuration, it is possible to reduce dispersion of the electrical characteristics of the P-type transistors pTr1, pTr2, pTr3 and pTr4.

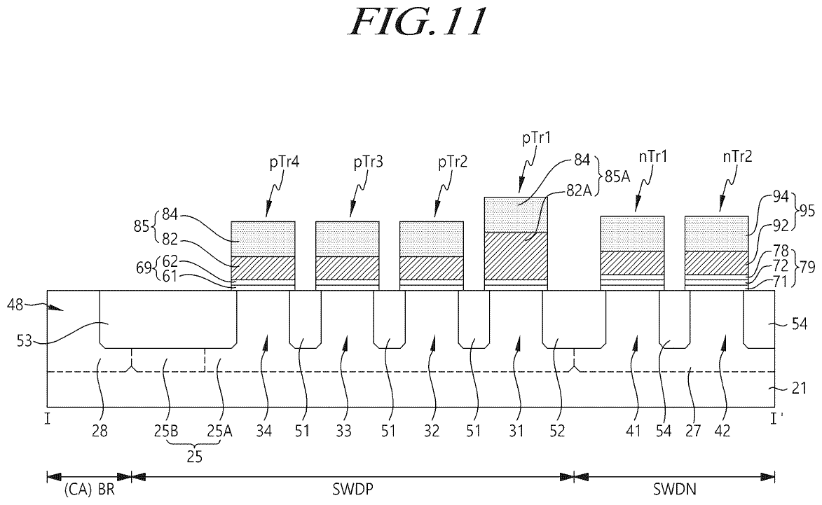

Referring to FIG. 11, the N-well 25 may include the first and second N-wells 25A and 25B. Dispersion of the N-type impurity concentrations (i.e., non-uniformity of the N-type impurity concentrations) of the N-type active regions 31, 32, 33 and 34 may be reduced. The second P-gate dielectric layer 69 and the first P-gate electrode 85A may be sequentially stacked over or, as illustrated, on the first N-type active region 31. The second P-gate dielectric layer 69 and the second P-gate electrode 85 may be sequentially stacked over or, as illustrated, on each of the second to fourth N-type active regions 32, 33 and 34. The N-gate dielectric layer 79 and the N-gate electrode 95 may be sequentially stacked over or, as illustrated, on each of the P-type active regions 41, 42, 43 and 44 (only 41 and 42 are illustrated for avoiding overcrowding the drawing). According to this configuration, it is possible to reduce dispersion of the electrical characteristics of the P-type transistors pTr1, pTr2, pTr3 and pTr4.

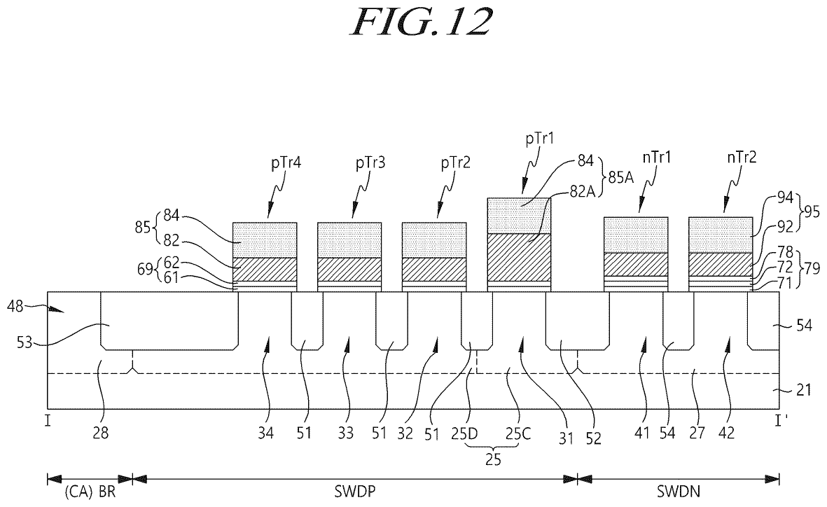

Referring to FIG. 12, the N-well 25 may include the third and fourth N-wells 25C and 25D. Dispersion of the N-type impurity concentrations (i.e., non-uniformity of the N-type impurity concentrations) of the N-type active regions 31, 32, 33 and 34 may be reduced. The second P-gate dielectric layer 69 and the first P-gate electrode 85A may be sequentially stacked over or, as illustrated, on the first N-type active region 31. The second P-gate dielectric layer 69 and the second P-gate electrode 85 may be sequentially stacked over or, as illustrated, on each of the second to fourth N-type active regions 32, 33 and 34. According to this configuration, it is possible to reduce dispersion of the electrical characteristics of the P-type transistors pTr1, pTr2, pTr3 and pTr4.

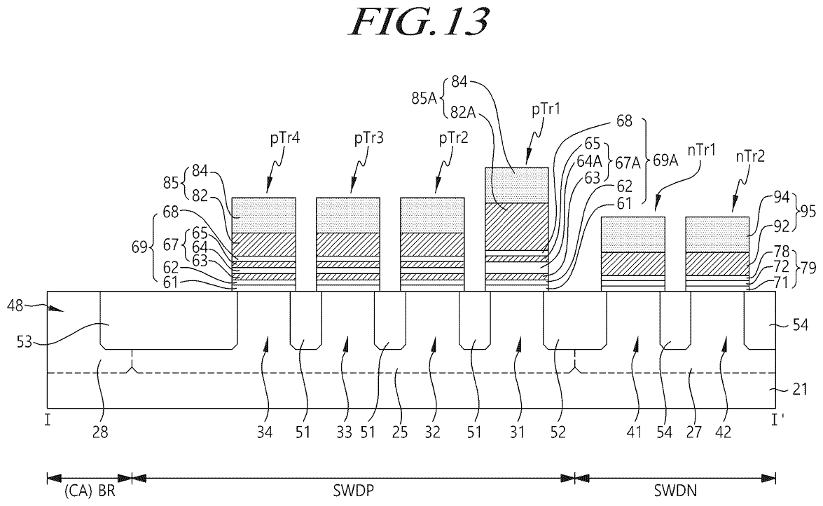

Referring to FIG. 13, the N-type impurity concentration of the first N-type active region 31 may be higher than the N-type impurity concentrations of the second to fourth N-type active regions 32, 33 and 34. The first P-gate dielectric layer 69A and the first P-gate electrode 85A may be sequentially stacked over or, as illustrated, on the first N-type active region 31. The second P-gate dielectric layer 69 and the second P-gate electrode 85 may be sequentially stacked over or, as illustrated, on each of the second to fourth N-type active regions 32, 33 and 34. The N-gate dielectric layer 79 and the N-gate electrode 95 may be sequentially stacked over or, as illustrated, on each of the P-type active regions 41, 42, 43 and 44 (only 41 and 42 are illustrated for avoiding overcrowding the drawing). According to this configuration, it is possible to reduce dispersion of the electrical characteristics of the P-type transistors pTr1, pTr2, pTr3 and pTr4.

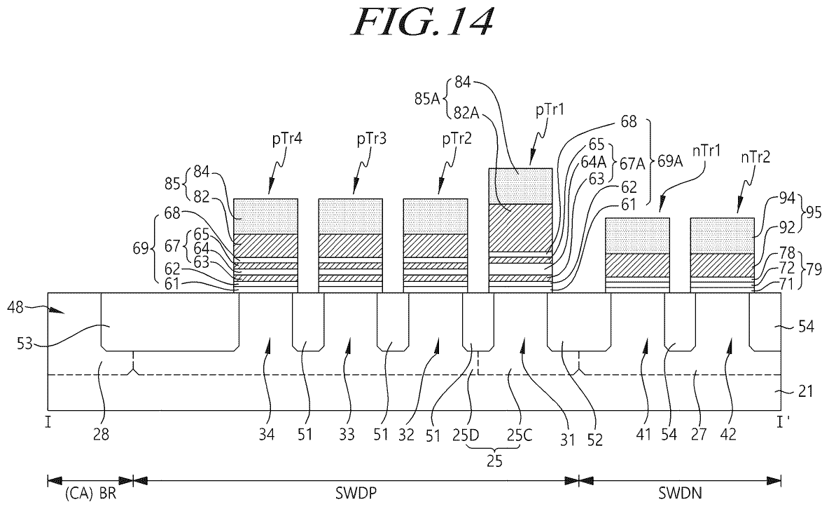

Referring to FIG. 14, the N-well 25 may include the third and fourth N-wells 25C and 25D. Dispersion of the N-type impurity concentrations (i.e., non-uniformity of the N-type impurity concentrations) of the N-type active regions 31, 32, 33 and 34 may be reduced. The first P-gate dielectric layer 69A and the first P-gate electrode 85A may be sequentially stacked over or, as illustrated, on the first N-type active region 31. The second P-gate dielectric layer 69 and the second P-gate electrode 85 may be sequentially stacked over or, as illustrated, on each of the second to fourth N-type active regions 32, 33 and 34. The N-gate dielectric layer 79 and the N-gate electrode 95 may be sequentially stacked over or, as illustrated, on each of the P-type active regions 41, 42, 43 and 44 (only 41 and 42 are illustrated for avoiding overcrowding the drawing). According to this configuration, it is possible to reduce dispersion of the electrical characteristics of the P-type transistors pTr1, pTr2, pTr3 and pTr4.

Referring to FIG. 15, a pair of P-source/drain regions 122 may be disposed in the first N-type active region 31 adjacent to both sides of the first P-gate electrode 85A. The pair of P-source/drain regions 122 may include P-type impurities. The first P-type transistor pTr1 (see FIG. 2) may include the first N-type active region 31, the first P-gate dielectric layer 69A, the first P-gate electrode 85A and the pair of the P-source/drain regions 122. Each of the P-type transistors pTr1, pTr2, pTr3 and pTr4 (see FIG. 2) may include a configuration similar to the pair of the P-source/drain regions 122.

Referring to FIG. 16, a pair of N-source/drain regions 124 may be disposed in the first P-type active region 41 adjacent to both sides of the N-gate electrode 95. The pair of N-source/drain regions 124 may include N-type impurities. The first N-type transistor nTr1 (see FIG. 2) may include the first P-type active region 41, the N-gate dielectric layer 79, the N-gate electrode 95 and the pair of N-source/drain regions 124. Each of the N-type transistors nTr1, nTr2, nTr3 and nTr4 (see FIG. 2) may include a configuration similar to the pair of N-source/drain regions 124.

Referring to FIG. 17, in some embodiments, the memory cells MC (see FIG. 2) based on some embodiments of the present disclosure may include DRAMs. The semiconductor device, according to some embodiments of the present disclosure may include substrate 21, second P-well 28, cell active region 148, cell isolation pattern 155, cell source/drain regions 174, gate capping layer 176, cell gate dielectric layer 179, word line WL, interlayer insulating layer 181, bit plug 182, bit line BL, storage contact plug SNC, landing pad LP, etch stop layer ES, lower electrode 191, support SP, capacitor dielectric layer 193, and upper electrode 195. The lower electrode 191, the capacitor dielectric layer 193 and the upper electrode 195 may configure cell capacitor 197. The word line WL may be electrically connected to the P-type transistors pTr1, pTr2, pTr3 and pTr4 (see FIG. 2) and/or the N-type transistors nTr1, nTr2, nTr3 and nTr4 (see FIG. 2).

The cell active region 148 may be delimited within the second P-well 28 by the cell isolation pattern 155. The cell active region 148 may include P-type impurities. The cell source/drain regions 174 may include N-type impurities.

The cell isolation pattern 155, the gate capping layer 176, the cell gate dielectric layer 179, the interlayer insulating layer 181, the etch stop layer ES, the support SP and the capacitor dielectric layer 193 may include silicon oxide, silicon nitride, silicon oxynitride, low-K dielectric, high-K dielectric or a combination thereof.

The word line WL, the bit plug 182, the bit line BL, the storage contact plug SNC, the landing pad LP, the lower electrode 191 and the upper electrode 195 may include a conductive material such as metal, metal oxide, metal nitride, metal silicide, polysilicon, conductive carbon or a combination thereof.

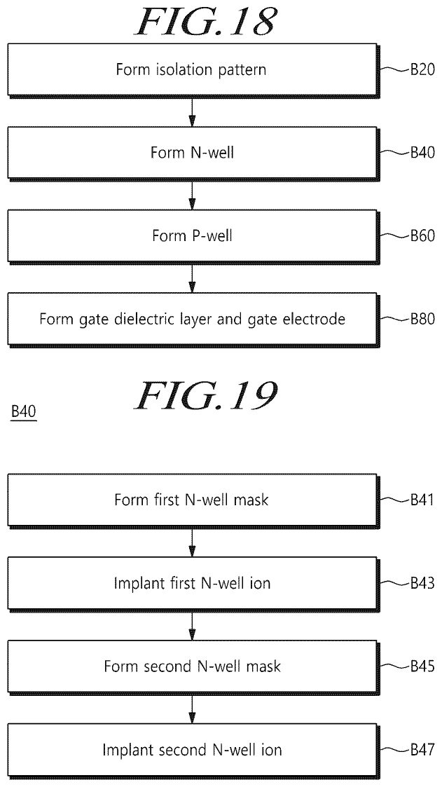

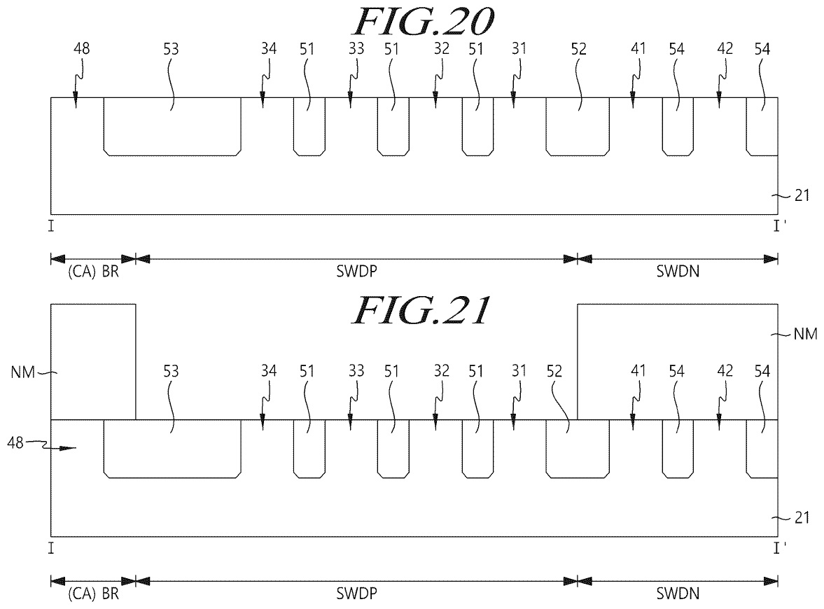

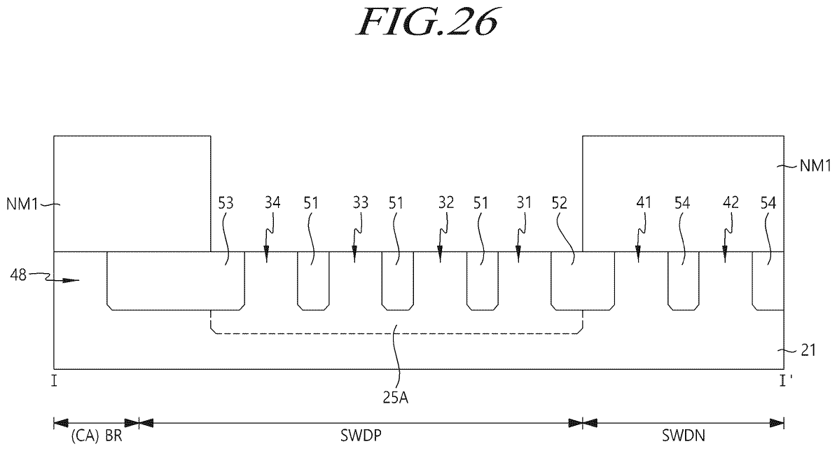

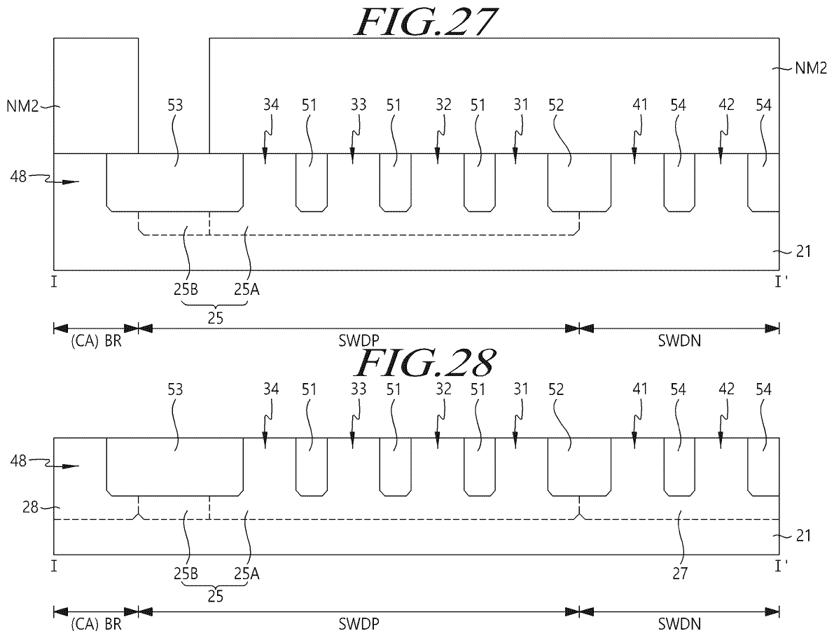

FIGS. 18 and 19 are flowcharts for describing a method of forming a semiconductor device based some embodiments of the present disclosure, and FIGS. 20 to 30 are cross-sectional views for describing the method of forming a semiconductor device based on some embodiments of the present disclosure. FIGS. 20 to 30 may be cross-sectional views taken along the line I-I′ of FIG. 2.

Referring to FIG. 18, the method of forming a semiconductor device based on some embodiments of the present disclosure may include forming an isolation pattern (B20), forming an N-well (B40), forming a P-well (B60) and forming a gate dielectric layer and a gate electrode (B80).

Referring to FIG. 19, in some embodiments, the forming the N-well (B40) may include forming a first N-well mask (B41), performing a first N-well ion implantation process (B43), forming a second N-well mask (B45) and performing a second N-well ion implantation process (B47).

Referring to FIGS. 18 and 20, isolation patterns 51, 52, 53 and 54 which delimit active regions 31, 32, 33, 34, 41, 42 and 48 may be formed on a substrate 21 (B20).

The substrate 21 may include a semiconductor substrate such as a silicon wafer or an SOI (silicon on insulator) wafer. The substrate 21 may include a III-V group semiconductor substrate, for example, a compound semiconductor substrate such as GaAs. The substrate 21 may include monocrystalline silicon, polysilicon, amorphous silicon, monocrystalline silicon germanium, polycrystalline silicon germanium, carbon-doped silicon, or a combination thereof. In some embodiments, the substrate 21 may be a monocrystalline silicon wafer with P-type impurities.

The active regions 31, 32, 33, 34, 41, 42 and 48 may be delimited within the substrate 21 by the isolation patterns 51, 52, 53 and 54. The isolation patterns 51, 52, 53 and 54 may be formed using a trench isolation method. Each of the isolation patterns 51, 52, 53 and 54 may include a single layer or a multilayer. The isolation patterns 51, 52, 53 and 54 may include at least two selected from the group consisting of Si, O, N, C and B. The isolation patterns 51, 52, 53 and 54 may include silicon oxide, silicon nitride, silicon oxynitride, low-k dielectric, high-k dielectric, or a combination thereof. For the sake of simplicity in description, the isolation patterns 51, 52, 53 and 54 are illustrated as having the same depth, but may be formed to have different depths.

Referring to FIGS. 18 and 21, an N-well mask NM which covers cell region CA (see FIG. 2), boundary region BR and N-type sub word line driver region SWDN and exposes P-type sub word line driver region SWDP may be formed on the substrate 21. The N-well mask NM may completely cover P-type active regions 41 and 42, dummy active region 48 and fourth isolation patterns 54. The N-well mask NM may be formed to cover a portion of a second isolation pattern 52 and a portion of third isolation pattern 53.

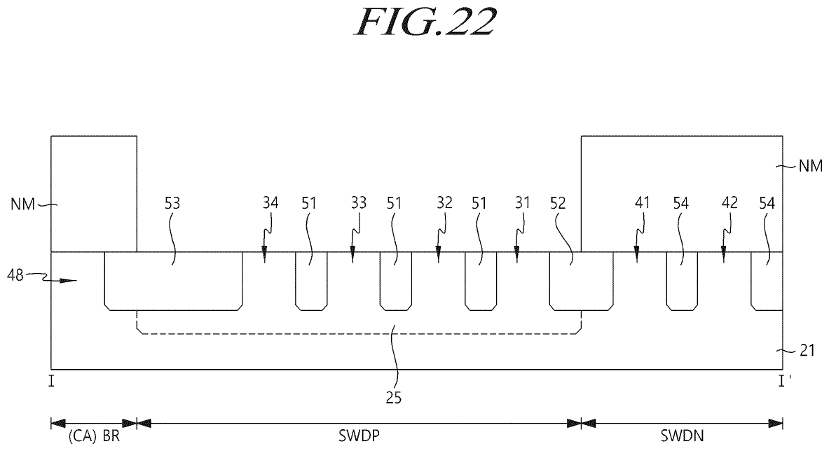

Referring to FIGS. 18 and 22, N-well 25 may be formed using the N-well mask NM as an ion implantation mask (B40). The N-well 25 may include N-type impurities such as phosphorus, arsenic or a combination thereof. The N-well 25 may be formed to a predetermined depth from the surface of the substrate 21. The lowermost end of the N-well 25 may be formed at a level lower than the lowermost ends of first isolation patterns 51, the second isolation pattern 52 and the third isolation pattern 53. The N-well 25 may be formed in the P-type sub word line driver region SWDP of the substrate 21. N-type active regions 31, 32, 33 and 34 may be delimited within the N-well 25. The N-type active regions 31, 32, 33 and 34 may include N-type impurities.

In some embodiments, the shortest distance between the N-well mask NM and a first N-type active region 31 may be smaller than the shortest distance between the N-well mask NM and a fourth N-type active region 34. Due to the well proximity effect (WPE), the N-type impurity concentration of the first N-type active region 31 may be different from the N-type impurity concentrations of second to fourth N-type active regions 32, 33 and 34. For example, the N-type impurity concentration of the first N-type active region 31 may be higher than the N-type impurity concentrations of the second to fourth N-type active regions 32, 33 and 34.

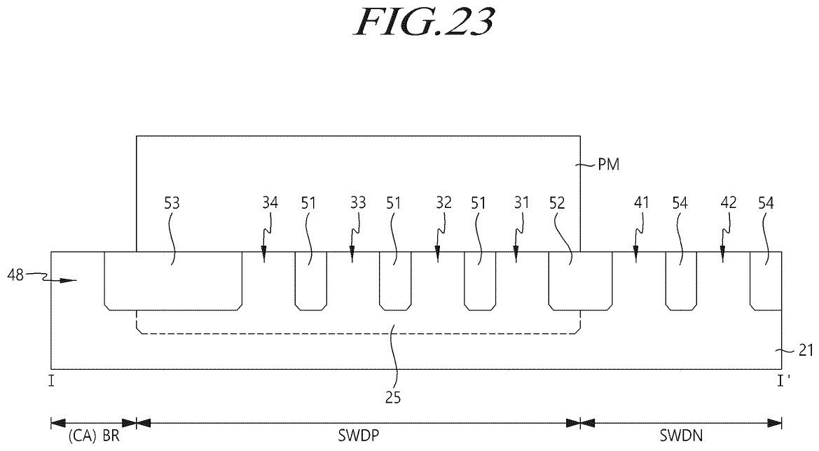

Referring to FIGS. 18 and 23, the N-well mask NM may be removed, a P-well mask PM which covers the P-type sub word line driver region SWDP and exposes the cell region CA (see FIG. 2), the boundary region BR and the N-type sub word line driver region SWDN may be formed on the substrate 21. The P-well mask PM may cover the N-well 25. The P-well mask PM may completely cover the N-type active regions 31, 32, 33 and 34 and the first isolation patterns 51. The P-well mask PM may be formed to cover a portion of the second isolation pattern 52 and a portion of the third isolation pattern 53.

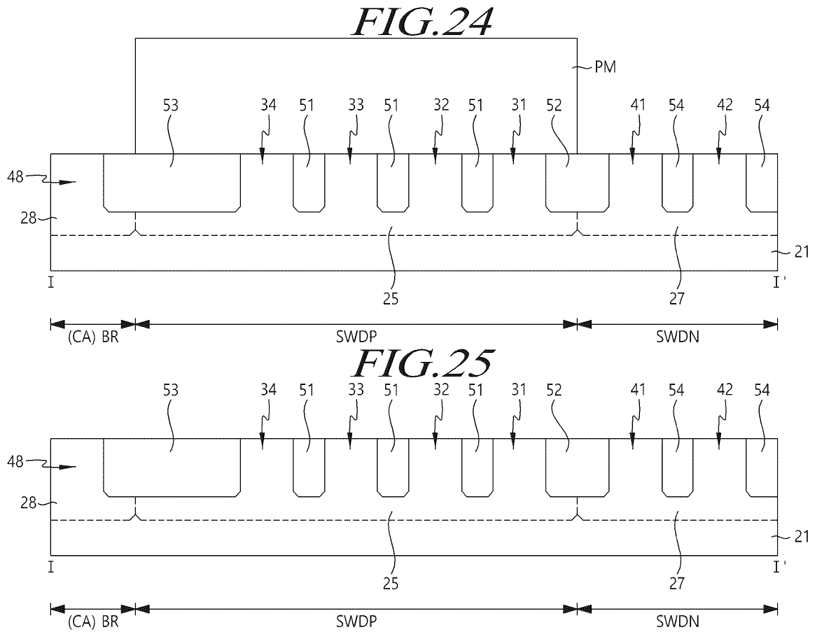

Referring to FIGS. 18 and 24, first P-well 27 and second P-well 28 may be formed using the P-well mask PM as an ion implantation mask (B60). The first P-well 27 and the second P-well 28 may include P-type impurities such as boron. The first P-well 27 and the second P-well 28 may be formed to a predetermined depth from the surface of the substrate 21. In some embodiments, the N-well 25, the first P-well 27 and the second P-well 28 may be formed to have different depths.

The lowermost end of the first P-well 27 may be formed at a level lower than the lowermost ends of the second isolation pattern 52 and the fourth isolation patterns 54. The first P-well 27 may be formed in the N-type sub word line driver region SWDN of the substrate 21. The P-type active regions 41 and 42 may be delimited within the first P-well 27. The boundary between the N-well 25 and the first P-well 27 may be located under the second isolation pattern 52. The lowermost end of the second P-well 28 may be formed at a level lower than the lowermost end of the third isolation pattern 53. The second P-well 28 may be formed in the cell region CA (see FIG. 2) and the boundary region BR of the substrate 21. The dummy active region 48 may be delimited within the second P-well 28. The boundary between the N-well 25 and the second P-well 28 may be formed under the third isolation pattern 53. The P-type active regions 41 and 42 and the dummy active region 48 may include P-type impurities.

Referring to FIGS. 18 and 25, the P-well mask PM may be removed. In some embodiments, the N-type impurity concentration of the first N-type active region 31 may be different from the N-type impurity concentrations of the second to fourth N-type active regions 32, 33 and 34. The N-type impurity concentration of the first N-type active region 31 may be higher than the N-type impurity concentrations of the second to fourth N-type active regions 32, 33 and 34.

Referring to FIGS. 18 and 3, gate dielectric layers 69, 69A and 79 and gate electrodes 85 and 95 may be formed on the substrate 21 in which the N-well 25, the first P-well 27, the second P-well 28, the active regions 31, 32, 33, 34, 41, 42 and 48 and the isolation patterns 51, 52, 53 and 54 are formed (B80).

The gate dielectric layers 69, 69A and 79 may include a first P-gate dielectric layer 69A, a second P-gate dielectric layer 69 and an N-gate dielectric layer 79. The first P-gate dielectric layer 69A may include a P-interface layer 61, a P-dielectric layer 62, a first modulation layer 67A and a P-capping layer 68. The first modulation layer 67A may include a lower modulation layer 63, a first intermediate modulation layer 64A and an upper modulation layer 65. The second P-gate dielectric layer 69 may include the P-interface layer 61, the P-dielectric layer 62, a second modulation layer 67 and the P-capping layer 68. The second modulation layer 67 may include the lower modulation layer 63, a second intermediate modulation layer 64 and the upper modulation layer 65. The N-gate dielectric layer 79 may include an N-interface layer 71, an N-dielectric layer 72 and an N-capping layer 78.

The gate electrodes 85 and 95 may include a second P-gate electrode 85 and an N-gate electrode 95. The second P-gate electrode 85 may include a second P-work function metal layer 82 and a P-gate conductive layer 84. The N-gate electrode 95 may include an N-work function metal layer 92 and an N-gate conductive layer 94.

Referring to FIGS. 18 and 8, gate dielectric layers 69 and 79 and gate electrodes 85, 85A and 95 may be formed on the substrate 21 in which the N-well 25, the first P-well 27, the second P-well 28, the active regions 31, 32, 33, 34, 41, 42 and 48 and the isolation patterns 51, 52, 53 and 54 are formed (B80).

The gate dielectric layers 69 and 79 may include the second P-gate dielectric layer 69 and the N-gate dielectric layer 79. The second P-gate dielectric layer 69 may include the P-interface layer 61 and the P-dielectric layer 62. The N-gate dielectric layer 79 may include the N-interface layer 71, the N-dielectric layer 72 and the N-capping layer 78.

The gate electrodes 85, 85A and 95 may include first P-gate electrode 85A, second P-gate electrode 85 and N-gate electrode 95. The first P-gate electrode 85A may include first P-work function metal layer 82A and P-gate conductive layer 84. The second P-gate electrode 85 may include the second P-work function metal layer 82 and the P-gate conductive layer 84. The N-gate electrode 95 may include the N-work function metal layer 92 and the N-gate conductive layer 94.

Referring to FIGS. 18, 19 and 26, a first N-well mask NM1 which covers the cell region CA (see FIG. 2), the boundary region BR and the N-type sub word line driver region SWDN and exposes a portion of the P-type sub word line driver region SWDP may be formed on the substrate 21 (B41). The remaining portion except the exposed portion of the P-type sub word line driver region SWDP on the substrate 21 may be covered with the first N-well mask NM1. A first N-well 25A may be formed by performing a first N-well ion implantation process using the first N-well mask NM1 as an ion implantation mask (B43).

In some embodiments, the shortest distance between the first N-well mask NM1 and the first N-type active region 31 may be substantially the same as the shortest distance between the first N-well mask NM1 and the fourth N-type active region 34. Due to reduction in the well proximity effect (WPE), dispersion of the N-type impurity concentrations (i.e., non-uniformity of the N-type impurity concentrations) of the N-type active regions 31, 32, 33 and 34 may be reduced.

Referring to FIGS. 18, 19 and 27, a second N-well mask NM2 which exposes only the portion of the P-type sub word line driver region SWDP covered by the first N-well mask NM1 may be formed on the substrate 21 (B45). The second N-well mask NM2 may cover the first N-well 25A. A second N-well 25B may be formed by performing a second N-well ion implantation process using the second N-well mask NM2 as an ion implantation mask (B47). The second N-well mask NM2 may be removed. The first and second N-wells 25A and 25B may configure the N-well 25.

In some embodiments, the boundary between the first and second N-wells 25A and 25B may be aligned or located under the third isolation pattern 53. The second N-well 25B may be delimited under the third isolation pattern 53. The N-type impurity concentration in the second N-well 25B may be different from the N-type impurity concentration in the first N-well 25A. The lower surfaces of the first and second N-wells 25A and 25B are illustrated as being formed at similar levels, but may be formed at different levels.

Referring to FIGS. 18, 19 and 28, a first P-well 27 and a second P-well 28 may be formed in a method similar to that described above with reference to FIGS. 24 and 25 (B60).

Referring to FIGS. 18, 19 and 4, the gate dielectric layers 69 and 79 and the gate electrodes 85 and 95 may be formed (B80). The gate dielectric layers 69 and 79 may include the second P-gate dielectric layer 69 and the N-gate dielectric layer 79. The second P-gate dielectric layer 69 may include the P-interface layer 61, the P-dielectric layer 62, the second modulation layer 67 and the P-capping layer 68. The second modulation layer 67 may include the lower modulation layer 63, the second intermediate modulation layer 64 and the upper modulation layer 65. The N-gate dielectric layer 79 may include the N-interface layer 71, the N-dielectric layer 72 and the N-capping layer 78. The gate electrodes 85 and 95 may include the second P-gate electrode 85 and the N-gate electrode 95. The second P-gate electrode 85 may include the second P-work function metal layer 82 and the P-gate conductive layer 84. The N-gate electrode 95 may include the N-work function metal layer 92 and the N-gate conductive layer 94.

Referring to FIGS. 18, 19 and 9, the gate dielectric layers 69 and 79 and the gate electrodes 85 and 95 may be formed (B80). The gate dielectric layers 69 and 79 may include the second P-gate dielectric layer 69 and the N-gate dielectric layer 79. The second P-gate dielectric layer 69 may include the P-interface layer 61 and the P-dielectric layer 62. The N-gate dielectric layer 79 may include the N-interface layer 71, the N-dielectric layer 72 and the N-capping layer 78. The gate electrodes 85 and 95 may include the second P-gate electrode 85 and the N-gate electrode 95. The second P-gate electrode 85 may include the second P-work function metal layer 82 and the P-gate conductive layer 84. The N-gate electrode 95 may include the N-work function metal layer 92 and the N-gate conductive layer 94.

Referring to FIGS. 18, 19 and 29, a third N-well 25C may be formed by performing a third N-well ion implantation process using the N-well mask NM (see FIG. 20) as an ion implantation mask in a method similar to that described above with reference to FIGS. 21 and 22. The third N-well 25C may be formed in a size similar to that of the N-well 25 of FIG. 22. The amount of N-type impurities implanted in the third N-well ion implantation process may be smaller than the amount of N-type impurities used in forming the N-well 25 of FIG. 22.

A third N-well mask NM3 which partially exposes the P-type sub word line driver region SWDP of the substrate 21 may be formed. The third N-well mask NM3 may cover a portion of the third N-well 25C and expose the remaining portion. The third N-well mask NM3 may cover the first N-type active region 31.

A fourth N-well 25D may be formed by performing a fourth N-well ion implantation process using the third N-well mask NM3 as an ion implantation mask. The remaining portion of the third N-well 25C which is not covered by the third N-well mask NM3 may be converted into the fourth N-well 25D. The first N-type active region 31 may be delimited within the third N-well 25C, and the second to fourth N-type active regions 32, 33 and 34 may be delimited within the fourth N-well 25D.

The third N-well mask NM3 may be removed. The third and fourth N-wells 25C and 25D may configure the N-well 25. The lower surfaces of the third and fourth N-wells 25C and 25D are illustrated as being formed at similar levels, but may be formed at different levels.

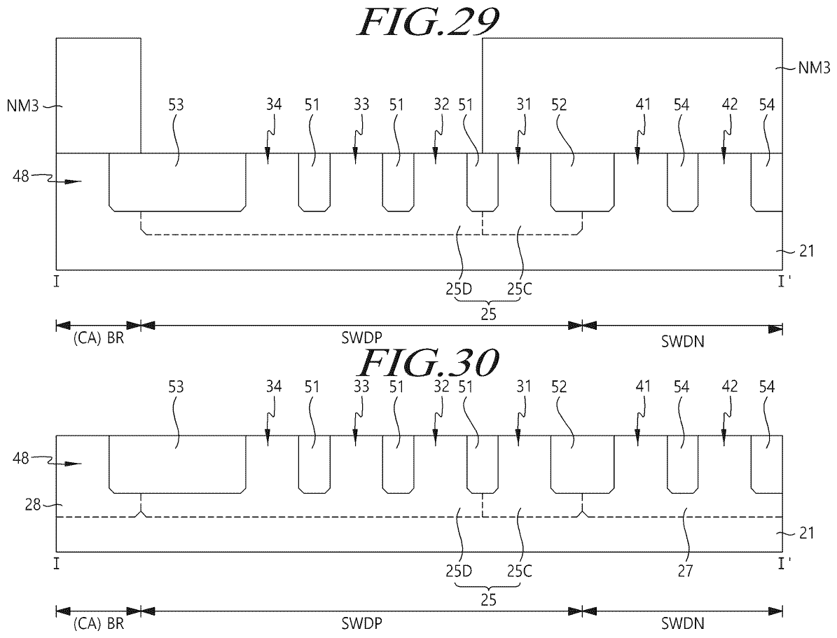

By applying different ion implantation masks such as the N-well mask NM (see FIG. 20) and the third N-well mask NM3 (see FIG. 29) and applying different ion implantation processes such as the third N-well ion implantation process and the fourth N-well ion implantation process performed sequentially, dispersion of the N-type impurity concentrations (i.e., non-uniformity of the N-type impurity concentrations) of the N-type active regions 31, 32, 33 and 34 may be reduced.

Referring to FIGS. 18, 19 and 30, the first P-well 27 and the second P-well 28 may be formed in a method similar to that described above with reference to FIGS. 24 and 25 (B60).

Referring to FIGS. 18, 19 and 5, the gate dielectric layers 69 and 79 and the gate electrodes 85 and 95 may be formed (B80). The gate dielectric layers 69 and 79 may include the second P-gate dielectric layer 69 and the N-gate dielectric layer 79. The second P-gate dielectric layer 69 may include the P-interface layer 61, the P-dielectric layer 62, the second modulation layer 67 and the P-capping layer 68. The second modulation layer 67 may include the lower modulation layer 63, the second intermediate modulation layer 64 and the upper modulation layer 65. The N-gate dielectric layer 79 may include the N-interface layer 71, the N-dielectric layer 72 and the N-capping layer 78. The gate electrodes 85 and 95 may include the second P-gate electrode 85 and the N-gate electrode 95. The second P-gate electrode 85 may include the second P-work function metal layer 82 and the P-gate conductive layer 84. The N-gate electrode 95 may include the N-work function metal layer 92 and the N-gate conductive layer 94.

Referring to FIGS. 18, 19 and 10, the gate dielectric layers 69 and 79 and the gate electrodes 85 and 95 may be formed (B80). The gate dielectric layers 69 and 79 may include the second P-gate dielectric layer 69 and the N-gate dielectric layer 79. The second P-gate dielectric layer 69 may include the P-interface layer 61 and the P-dielectric layer 62. The N-gate dielectric layer 79 may include the N-interface layer 71, the N-dielectric layer 72 and the N-capping layer 78. The gate electrodes 85 and 95 may include the second P-gate electrode 85 and the N-gate electrode 95. The second P-gate electrode 85 may include the second P-work function metal layer 82 and the P-gate conductive layer 84. The N-gate electrode 95 may include the N-work function metal layer 92 and the N-gate conductive layer 94.

Statement 1. A semiconductor device comprising:
a first P-well, a second P-well and an N-well between the first P-well and the second P-well in a substrate;
a plurality of N-type active regions delimited within the N-well, the plurality of N-type active regions including a first N-type active region adjacent to the first P-well and a second N-type active region adjacent to the second P-well, a shortest distance between a boundary of the second P-well and the N-well and the second N-type active region being larger than a shortest distance between a boundary of the first P-well and the N-well and the first N-type active region;
a first P-gate electrode including a first P-work function metal layer on the first N-type active region;
a second P-gate electrode including a second P-work function metal layer on the second N-type active region, the first P-work function metal layer being thicker than the second P-work function metal layer; and
P-gate dielectric layers between the first N-type active region and the first P-gate electrode and between the second N-type active region and the second P-gate electrode.

Statement 2. The semiconductor device according to Statement 1, wherein each of the first P-work function metal layer and the second P-work function metal layer includes TiN, TiCN, TaN, WN, TiAl, MoN or a combination thereof.

Statement 3. The semiconductor device according to Statement 1, wherein an N-type impurity concentration of the first N-type active region is higher than that of the second N-type active region.

Statement 4. The semiconductor device according to Statement 1, further comprising:
a P-type active region delimited within the first P-well;
a plurality of first isolation patterns between the plurality of N-type active regions;
a second isolation pattern between the P-type active region and the first N-type active region; and
a third isolation pattern adjacent to a boundary between the second P-well and the N-well and having a horizontal width larger than the second isolation pattern.

Statement 5. The semiconductor device according to Statement 4, wherein
a boundary of the N-well and the first P-well is aligned under the second isolation pattern, and
a boundary of the N-well and the second P-well is aligned under the third isolation pattern.

Statement 6. The semiconductor device according to Statement 4, further comprising:
an N-gate dielectric layer on the P-type active region; and
an N-gate electrode on the N-gate dielectric layer,
wherein the N-gate dielectric layer includes an N-interface layer, an N-dielectric layer and an N-capping layer which are sequentially stacked.

Statement 7. The semiconductor device according to Statement 6, wherein
the N-interface layer includes silicon oxide, silicon oxynitride or a combination thereof,
the N-dielectric layer includes HfSiON, HfO2, HfON, SION, ZrSiO4, Y2O3, Ta2O5, BaO, HfSiO, MgO, Al2O3, Si3N4, CaO, LaLuO2 or a combination thereof, and
the N-capping layer includes LaO, La2O3, Y2O3, ScO2 or a combination thereof.

Statement 8. The semiconductor device according to Statement 1, wherein each of the P-gate dielectric layers includes a P-interface layer and a P-dielectric layer which are sequentially stacked.

Statement 9. The semiconductor device according to Statement 8, wherein
the P-dielectric layer includes HfSiON, HfO2, HfON, SION, ZrSiO4, Y2O3, Ta2O5, BaO, HfSiO, MgO, Al2O3, Si3N4, CaO, LaLuO2 or a combination thereof, and
the P-interface layer includes silicon oxide, silicon oxynitride or a combination thereof.

Statement 10. The semiconductor device according to Statement 1, wherein
the N-well includes a first N-well adjacent to the first P-well and a second N-well adjacent to the second P-well, and
the plurality of N-type active regions are delimited within the first N-well.

Statement 11. The semiconductor device according to Statement 10, wherein a shortest distance between a boundary of the first P-well and the first N-well and the first N-type active region is substantially the same as a shortest distance between a boundary of the first N-well and the second N-well and the second N-type active region.

Statement 12. The semiconductor device according to Statement 10, wherein an N-type impurity concentration in the second N-well is different from an N-type impurity concentration in the first N-well.

Statement 13. The semiconductor device according to Statement 1, wherein
the N-well includes a first N-well adjacent to the first P-well and a second N-well adjacent to the second P-well,
the first N-type active region is delimited within the first N-well, and
the second N-type active region is delimited within the second N-well.

Statement 14. The semiconductor device according to Statement 13, wherein a shortest distance between a boundary of the second P-well and the second N-well and the second N-type active region is larger than a shortest distance between a boundary of the first P-well and the first N-well and the first N-type active region.

Statement 15. A semiconductor device comprising:
a first P-well, a second P-well and an N-well including a first N-well and a second N-well between the first P-well and the second P-well in a substrate, the first N-well being adjacent to the first P-well, the second N-well being adjacent to the second P-well;
a plurality of N-type active regions delimited within the first N-well, the plurality of N-type active regions including a first N-type active region adjacent to the first P-well and a second N-type active region adjacent to the second N-well, a shortest distance between a boundary of the first P-well and the first N-well and the first N-type active region being substantially the same as a shortest distance between a boundary of the first N-well and the second N-well and the second N-type active region;
P-gate dielectric layers on the first N-type active region and the second N-type active region; and
P-gate electrodes on the P-gate dielectric layers.

Statement 16. The semiconductor device according to Statement 15, wherein an N-type impurity concentration in the second N-well is different from an N-type impurity concentration in the first N-well.

Statement 17. The semiconductor device according to Statement 15, wherein each of the P-gate dielectric layers includes a P-interface layer and a P-dielectric layer which are sequentially stacked.

Statement 18. The semiconductor device according to Statement 17, wherein
the P-dielectric layer includes HfSiON, HfO2, HfON, SION, ZrSiO4, Y2O3, Ta2O5, Bao, HfSiO, MgO, Al2O3, Si3N4, CaO, LaLuO2 or a combination thereof, and
the P-interface layer includes silicon oxide, silicon oxynitride or a combination thereof.

Statement 19. The semiconductor device according to Statement 17, wherein each of the P-gate dielectric layers further includes a modulation layer which is disposed on the P-dielectric layer and includes a lower modulation layer, an intermediate modulation layer and an upper modulation layer which are sequentially stacked.

Statement 20. The semiconductor device according to Statement 19, wherein each of the lower modulation layer and the upper modulation layer includes TiN, TiCN, TaN, WN, TiAl, MoN or a combination thereof, and the intermediate modulation layer includes Al2O3, HfO2 or a combination thereof.

Statement 21. The semiconductor device according to Statement 19, wherein each of the P-gate dielectric layers further includes a P-capping layer on the modulation layer.

Statement 22. The semiconductor device according to Statement 21, wherein the P-capping layer includes LaO, La2O3, Y2O3, ScO2 or a combination thereof.

Statement 23. The semiconductor device according Statement 15, further comprising:
a P-type active region delimited within the first P-well;
a plurality of first isolation patterns between the plurality of N-type active regions;
a second isolation pattern between the P-type active region and the first N-type active region; and
a third isolation pattern adjacent to a boundary between the second P-well and the N-well and having a horizontal width larger than the second isolation pattern.

Statement 24. The semiconductor device according Statement 23, wherein
a boundary of the first N-well and the first P-well is aligned under the second isolation pattern, and
a boundary of the second N-well and the second P-well is aligned under the third isolation pattern.

Statement 25. The semiconductor device according to Statement 24, wherein a boundary of the first N-well and the second N-well is aligned under the third isolation pattern.

Statement 26. The semiconductor device according to Statement 23, further comprising:
an N-gate dielectric layer on the P-type active region; and
an N-gate electrode on the N-gate dielectric layer,
wherein the N-gate dielectric layer includes an N-interface layer, an N-dielectric layer and an N-capping layer which are sequentially stacked.

Statement 27. The semiconductor device according to Statement 26, wherein
the N-interface layer includes silicon oxide, silicon oxynitride or a combination thereof,
the N-dielectric layer includes HfSiON, HfO2, HfON, SION, ZrSiO4, Y2O3, Ta2O5, BaO, HfSiO, MgO, Al2O3, Si3N4, CaO, LaLuO2 or a combination thereof, and
the N-capping layer includes LaO, La2O3, Y2O3, ScO2 or a combination thereof.

Statement 28. A semiconductor device comprising:
a first P-well, a second P-well and an N-well including a first N-well and a second N-well between the first P-well and the second P-well in a substrate, the first N-well being adjacent to the first P-well, the second N-well being adjacent to the second P-well;
a plurality of N-type active regions delimited within the N-well, the plurality of N-type active regions including a first N-type active region adjacent to the first P-well and delimited within the first N-well and a second N-type active region adjacent to the second P-well and delimited within the second N-well, a shortest distance between a boundary of the second P-well and the second N-well and the second N-type active region being larger than a shortest distance between a boundary of the first P-well and the first N-well and the first N-type active region;
P-gate dielectric layers on the first N-type active region and the second N-type active region; and
P-gate electrodes on the P-gate dielectric layers.

Statement 29. The semiconductor device according to Statement 28, further comprising:
a P-type active region delimited within the first P-well;
a plurality of first isolation patterns between the plurality of N-type active regions;
a second isolation pattern between the P-type active region and the first N-type active region; and
a third isolation pattern adjacent to a boundary between the second P-well and the N-well and having a horizontal width larger than the second isolation pattern.

Statement 30. The semiconductor device according to Statement 29, wherein
a boundary of the first N-well and the first P-well is aligned under the second isolation pattern, and
a boundary of the second N-well and the second P-well is aligned under the third isolation pattern.

Statement 31. The semiconductor device according Statement 29,
wherein the plurality of N-type active regions further include:
a third N-type active region between the first N-type active region and the second N-type active region; and
a fourth N-type active region between the second N-type active region and the third N-type active region, and
wherein a boundary of the first N-well and the second N-well is aligned under the first isolation pattern between the first N-type active region and the third N-type active region.

Statement 32. The semiconductor device according to Statement 29, further comprising:
an N-gate dielectric layer on the P-type active region; and
an N-gate electrode on the N-gate dielectric layer,
wherein the N-gate dielectric layer includes an N-interface layer, an N-dielectric layer and an N-capping layer which are sequentially stacked.

Statement 33. The semiconductor device according Statement 32, wherein
the N-interface layer includes silicon oxide, silicon oxynitride or a combination thereof,
the N-dielectric layer includes HfSiON, HfO2, HfON, SION, ZrSiO4, Y2O3, Ta2O5, BaO, HfSiO, MgO, Al2O3, Si3N4, CaO, LaLuO2 or a combination thereof, and
the N-capping layer includes LaO, La2O3, Y2O3, ScO2 or a combination thereof.

Statement 34. The semiconductor device according to Statement 28, wherein each of the P-gate dielectric layers includes a P-interface layer and a P-dielectric layer which are sequentially stacked.

Statement 35. The semiconductor device according Statement 34, wherein
the P-dielectric layer includes HfSiON, HfO2, HfON, SION, ZrSiO4, Y2O3, Ta2O5, BaO, HfSiO, MgO, Al2O3, Si3N4, CaO, LaLuO2 or a combination thereof, and
the P-interface layer includes silicon oxide, silicon oxynitride or a combination thereof.

Statement 36. The semiconductor device according to Statement 34, wherein each of the P-gate dielectric layers further includes a modulation layer which is disposed on the P-dielectric layer and includes a lower modulation layer, an intermediate modulation layer and an upper modulation layer which are sequentially stacked.

Statement 37. The semiconductor device according to Statement 36, wherein
each of the lower modulation layer and the upper modulation layer includes TiN, TiCN, TaN, WN, TiAl, MoN or a combination thereof, and
the intermediate modulation layer includes Al2O3, HfO2 or a combination thereof.

Statement 38. The semiconductor device according to Statement 36, wherein each of the P-gate dielectric layers further includes a P-capping layer on the modulation layer.

Statement 39. The semiconductor device according to Statement 38, wherein the P-capping layer includes LaO, La2O3, Y2O3, ScO2 or a combination thereof.

Statement 40. A semiconductor device comprising:
a first P-well, a second P-well and an N-well including a first N-well and a second N-well between the first P-well and the second P-well in a substrate, the first N-well being adjacent to the first P-well, the second N-well being adjacent to the second P-well;
a plurality of N-type active regions delimited within the N-well, the plurality of N-type active regions including a first N-type active region adjacent to the first P-well and delimited within the first N-well and a second N-type active region adjacent to the second P-well and delimited within the second N-well, a shortest distance between a boundary of the second P-well and the second N-well and the second N-type active region being larger than a shortest distance between a boundary of the first P-well and the first N-well and the first N-type active region;
a first P-gate dielectric layer disposed on the first N-type active region and including a first modulation layer;
a second P-gate dielectric layer disposed on the second N-type active region and including a second modulation layer, the first modulation layer being thicker than the second modulation layer;
a first P-gate electrode including a first P-work function metal layer on the first P-gate dielectric layer; and
a second P-gate electrode including a second P-work function metal layer on the second P-gate dielectric layer,
wherein the first P-work function metal layer is thicker than the second P-work function metal layer.

Although various embodiments of the present disclosure have been described for illustrative purposes, those skilled in the art will appreciate that various modifications, additions and substitutions are possible, without departing from the scope and spirit of the present disclosure. Therefore, the embodiments disclosed above and in the accompanying drawings should be considered in a descriptive sense only and not for limiting the technological scope of the present 5 disclosure. The technological scope of the present disclosure is not limited by the embodiments and the accompanying drawings. The scope of the present disclosure should be interpreted in connection with the appended claims and encompass all equivalents falling within the scope of the appended claims. Furthermore, the embodiments may be combined to form additional embodiments.

What is claimed is:

1. A semiconductor device comprising:
a first P-well, a second P-well and an N-well formed in a substrate with the N-well positioned between the first P-well and the second P-well;
a plurality of N-type active regions delimited within the N-well, the plurality of N-type active regions including a first N-type active region adjacent to the first P-well and a second N-type active region adjacent to the second P-well, a shortest distance between a boundary of the second P-well and the N-well and the second N-type active region being larger than a shortest distance between a boundary of the first P-well and the N-well and the first N-type active region;
a first P-gate dielectric layer disposed on the first N-type active region and including a first modulation layer;
a second P-gate dielectric layer disposed on the second N-type active region and including a second modulation layer;
a first P-gate electrode on the first P-gate dielectric layer; and
a second P-gate electrode on the second P-gate dielectric layer.

2. The semiconductor device according to claim 1,
wherein the first modulation layer includes a first intermediate modulation layer between a lower modulation layer and an upper modulation layer,
wherein the second modulation layer includes a second intermediate modulation layer between the lower modulation layer and the upper modulation layer, the first intermediate modulation layer being thicker than the second intermediate modulation layer, wherein each of the first intermediate modulation layer and the second intermediate modulation layer includes Al2O3, HfO2 or a combination thereof.

3. The semiconductor device according to claim 2, wherein each of the lower modulation layer and the upper modulation layer includes TiN, TiCN, TaN, WN, TiAl, MoN or a combination thereof.

4. The semiconductor device according to claim 1, wherein an N-type impurity concentration of the first N-type active region is higher than that of the second N-type active region.

5. The semiconductor device according to claim 1, further comprising:
a P-type active region delimited within the first P-well;
a plurality of first isolation patterns between the plurality of N-type active regions;
a second isolation pattern between the P-type active region and the first N-type active region; and
a third isolation pattern adjacent to a boundary between the second P-well and the N-well, and having a horizontal width larger than the second isolation pattern.

6. The semiconductor device according to claim 5, wherein
a boundary between the N-well and the first P-well is aligned under the second isolation pattern, and
a boundary between the N-well and the second P-well is aligned under the third isolation pattern.

7. The semiconductor device according to claim 5, further comprising:
an N-gate dielectric layer on the P-type active region; and
an N-gate electrode on the N-gate dielectric layer,
wherein the N-gate dielectric layer includes an N-interface layer, an N-dielectric layer and an N-capping layer which are sequentially stacked.

8. The semiconductor device according to claim 7, wherein
the N-interface layer includes silicon oxide, silicon oxynitride or a combination thereof,
the N-dielectric layer includes HfSiON, HfO2, HfON, SiON, ZrSiO4, Y2O3, Ta2O5, BaO, HfSiO, MgO, Al2O3, Si3N4, CaO, LaLuO2 or a combination thereof, and
the N-capping layer includes LaO, La2O3, Y2O3, ScO2 or a combination thereof.

9. The semiconductor device according to claim 1,
wherein the first P-gate dielectric layer further includes:
a P-dielectric layer between the first modulation layer and the first N-type active region; and
a P-interface layer between the P-dielectric layer and the first N-type active region, and
wherein the second P-gate dielectric layer further includes:
the P-dielectric layer between the second modulation layer and the second N-type active region; and
the P-interface layer between the P-dielectric layer and the second N-type active region.

10. The semiconductor device according to claim 9, wherein
the P-dielectric layer includes HfSiON, HfO2, HfON, SiON, ZrSiO4, Y2O3, Ta2O5, BaO, HfSiO, MgO, Al2O3, Si3N4, CaO, LaLuO2 or a combination thereof, and
the P-interface layer includes silicon oxide, silicon oxynitride or a combination thereof.

11. The semiconductor device according to claim 1, wherein
the first P-gate dielectric layer further includes a P-capping layer between the first modulation layer and the first P-gate electrode, and
the second P-gate dielectric layer further includes the P-capping layer between the second modulation layer and the second P-gate electrode.

12. The semiconductor device according to claim 11, wherein the P-capping layer includes LaO, La2O3, Y2O3, ScO2 or a combination thereof.

13. The semiconductor device according to claim 1, wherein
the first P-gate electrode includes a first P-work function metal layer on the first P-gate dielectric layer,
the second P-gate electrode includes a second P-work function metal layer on the second P-gate dielectric layer, and
the first P-work function metal layer is thicker than the second P-work function metal layer.

14. The semiconductor device according to claim 13, wherein the first P-work function metal layer and the second P-work function metal layer include TiN, TiCN, TaN, WN, TiAl, MoN or a combination thereof.

15. The semiconductor device according to claim 1, wherein
the N-well includes a first N-well adjacent to the first P-well and a second N-well adjacent to the second P-well, and
the plurality of N-type active regions are delimited within the first N-well.

16. The semiconductor device according to claim 15, wherein a shortest distance between a boundary of the first P-well and the first N-well and the first N-type active region is substantially the same as a shortest distance between a boundary of the first N-well and the second N-well and the second N-type active region.

17. The semiconductor device according to claim 15, wherein an N-type impurity concentration in the second N-well is different from an N-type impurity concentration in the first N-well.

18. The semiconductor device according to claim 1, wherein
the N-well includes a first N-well adjacent to the first P-well and a second N-well adjacent to the second P-well,
the first N-type active region is delimited within the first N-well, and
the second N-type active region is delimited within the second N-well.

19. The semiconductor device according to claim 18, wherein a shortest distance between a boundary of the second P-well and the second N-well and the second N-type active region is larger than a shortest distance between a boundary of the first P-well and the first N-well and the first N-type active region.

20. A semiconductor device comprising:
a first P-well, a second P-well and an N-well including a first N-well and a second N-well between the first P-well and the second P-well in a substrate, the first N-well being adjacent to the first P-well, the second N-well being adjacent to the second P-well;
a plurality of N-type active regions delimited within the first N-well, the plurality of N-type active regions including a first N-type active region adjacent to the first P-well and a second N-type active region adjacent to the second N-well, a shortest distance between a boundary of the first P-well and the first N-well and the first N-type active region being substantially the same as a shortest distance between a boundary of the first N-well and the second N-well and the second N-type active region;
a first P-gate dielectric layer disposed on the first N-type active region and including a first modulation layer;
a second P-gate dielectric layer disposed on the second N-type active region and including a second modulation layer, the first modulation layer being thicker than the second modulation layer;
a first P-gate electrode including a first P-work function metal layer on the first P-gate dielectric layer; and
a second P-gate electrode including a second P-work function metal layer on the second P-gate dielectric layer,
wherein the first P-work function metal layer is thicker than the second P-work function metal layer.
